(19) United States
(12) Patent Application Publication
(10) Pub. No.: US 2025/0218872 A1
(43) Pub. Date: Jul. 3, 2025

(54) EXPANDING DEVICE, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka (JP)

(72) Inventor: Yoshikuni SUZUKI, Iwata-shi (JP)

(73) Assignee: YAMAHA HATSUDOKI KABUSHIKI KAISHA, Iwata-shi, Shizuoka (JP)

(21) Appl. No.: 18/848,493

(22) PCT Filed: Apr. 27, 2022
(86) PCT No.: PCT/JP2022/019143

§ 371 Date: Sep. 18, 2024

(51) Int. Cl. H01L 21/78; H01L 21/67; H01L 21/683; H01L 21/687

(52) U.S. Cl. CPC H01L 21/78; H01L 21/67259; H01L 21/6838; H01L 21/68707

(57) ABSTRACT

An expanding device includes a clamp unit, an expanding ring, and an imager to image an expanded state of a wafer by the expanding ring at a plurality of timings from a start of expansion of a sheet member to an end of expansion of the sheet member.

### CROSS-REFERENCE TO RELATED APPLICATION

This application is a National Stage of International Patent Application No. PCT/JP2022/019143, filed Apr. 27, 2022, the entire content of which is incorporated herein by reference.

### BACKGROUND

### Technical Field

The present disclosure relates to an expanding device, a semiconductor chip manufacturing method, and a semiconductor chip, and more particularly, it relates to an expanding device including an expanding ring to divide a wafer into a plurality of semiconductor chips, a semiconductor chip manufacturing method, and a semiconductor chip.

### Background Art

Conventionally, an expanding device including an expanding ring to divide a wafer into a plurality of semiconductor chips is known. Such an expanding device is disclosed in Japanese Patent Laid-Open No. 2011-211053, for example.

Japanese Patent Laid-Open No. 2011-211053 discloses an expanding device including a cylindrical portion to divide a wafer into a plurality of chips. The expanding device includes a support (clamp unit), the cylindrical portion, and an imager. The support supports (holds) a processing object including a wafer bonded to an adhesive sheet. The cylindrical portion expands the adhesive sheet supported by the support to divide the wafer into the plurality of chips. The imager measures an interval between the plurality of chips after the wafer is divided into the plurality of chips. Thus, the expanding device can detect a portion in which the interval between the plurality of chips is not expanded (a portion that is not divided).

### SUMMARY

In the expanding device disclosed in Japanese Patent Laid-Open No. 2011-211053, the wafer is divided into the plurality of chips, and then the interval between the plurality of chips is measured. Therefore, when the adhesive sheet of the processing object is being expanded, it is not possible to detect whether or not the plurality of separated chips have been separated near the end of the expansion. When the plurality of chips have been separated near the end of the expansion of the adhesive sheet, it is highly likely that a wafer will not be divided into a plurality of chips due to a slight change such as the same adhesive sheet being slightly softer or a modified layer of the wafer being formed a little smaller at the next or subsequent adhesive sheet expansion. In such a case, the imager of the expanding device disclosed in Japanese Patent Laid-Open No. 2011-211053 measures the interval between the plurality of chips after the wafer is divided into the plurality of chips, and thus it is not possible to acquire an event that is considered to be highly likely to prevent the wafer from being divided into the plurality of chips. Therefore, the expanding device disclosed in Japanese Patent Laid-Open No. 2011-211053 cannot acquire an event that is predicted to prevent the wafer from being divided into the plurality of chips, and thus it is difficult to prevent the possibility that the wafer will not be divided into the plurality of chips.

Accordingly, the present disclosure provides an expanding device, a semiconductor chip manufacturing method, and a semiconductor chip each capable of preventing the possibility that a wafer will not be divided into a plurality of chips.

An expanding device according to a first aspect of the present disclosure includes a clamp unit to hold a wafer ring structure including an elastic sheet member to which a wafer to be divided along a dividing line into a plurality of semiconductor chips has been attached, an expanding ring to divide the wafer into the plurality of semiconductor chips spaced apart from each other by expanding the sheet member while the clamp unit holds the wafer ring structure, and an imager to image an expanded state of the wafer by the expanding ring at a plurality of timings from a start of expansion of the sheet member to an end of expansion of the sheet member.

As described above, the expanding device according to the first aspect of the present disclosure includes the imager to image the expanded state of the wafer by the expanding ring at the plurality of timings from the start of expansion of the sheet member to the end of expansion of the sheet member. Accordingly, the expanded state (divided state) of the wafer near the end of expansion can be acquired based on an image captured at a timing near the end of expansion among the plurality of timings of imaging by the imager, and thus it is possible to detect whether or not the plurality of separated semiconductor chips have been separated near the end of expansion. When the plurality of semiconductor chips have been separated near the end of expansion of the sheet member, it is highly likely that the wafer will not be divided into the plurality of semiconductor chips due to a slight change such as the same sheet member being slightly softer or a modified layer of the wafer being formed a little smaller at the next or subsequent expansion of the sheet member. In this regard, according to the present disclosure, the expanded state (divided state) of the wafer near the end of expansion of the sheet member is acquired such that it is possible to acquire an event that is considered to be highly likely to prevent the wafer from being divided into the plurality of semiconductor chips. Consequently, it is possible to acquire an event that is predicted to prevent the wafer from being divided into the plurality of semiconductor chips, and thus it is possible to prevent the possibility that the wafer will not be divided into the plurality of semiconductor chips.

In the expanding device according to the first aspect, the imager is preferably operable to capture a moving image including a plurality of captured images obtained by imaging the expanded state of the wafer by the expanding ring at a plurality of consecutive timings from the start of expansion of the sheet member to the end of expansion of the sheet member. Accordingly, the moving image including the plurality of captured images is captured by the imager such that the expanded state of the wafer from the start of expansion of the sheet member to the end of expansion of the sheet member can be reliably and completely acquired, and thus the timing at which the plurality of semiconductor chips have been separated can be accurately acquired.

The expanding device according to the first aspect preferably further includes an expansion maintaining member to maintain an expanded state of the sheet member in a vicinity of the wafer, and the imager is preferably attached to the expansion maintaining member. Accordingly, it is not necessary to provide a dedicated mounting member to attach the imager to the expanding device, and thus an increase in the number of components of the expanding device and the complexity of the structure can be reduced or prevented.

In such a case, the expansion maintaining member preferably includes a cylindrical pressing ring surrounding the wafer, and a lid to cover the pressing ring, and the imager is preferably attached to the lid of the expansion maintaining member. Accordingly, the lid is provided at a position at which the upward opening of the cylindrical pressing ring surrounding the wafer is covered, and thus the imager can be arranged above the wafer. Consequently, the imager images the wafer from above such that it is possible to easily image the plurality of semiconductor chips that are separated and spaced apart from each other.

In the expanding device in which the imager is in the lid, the imager is preferably in a central portion of the lid in a radial direction of the pressing ring. Accordingly, the entire wafer surrounded by the cylindrical pressing ring can be easily imaged from above by the imager.

The expanding device including the expansion maintaining member preferably further includes a member movement mechanism to move the expansion maintaining member in an upward-downward direction, and the imager is preferably operable to image the expanded state of the wafer by the expanding ring in a state in which the expansion maintaining member lowered by the member movement mechanism covers the wafer. Accordingly, the expanded state of the wafer can be imaged by the imager at a closer position, and thus it is possible to acquire an image in which division of the wafer into the plurality of semiconductor chips is more clearly imaged.

The expanding device including the expansion maintaining member including the lid preferably further includes an ultraviolet irradiator at a position in a downward direction with respect to the imager to irradiate the sheet member in the expanded state with ultraviolet rays from below, and the expansion maintaining member is preferably operable to cover the wafer from above with the cylindrical pressing ring and the lid such that the ultraviolet rays radiated from the ultraviolet irradiator to the sheet member do not leak from the expansion maintaining member to an outside. Accordingly, the expansion maintaining member can be used not only as a mounting member for the imager but also as a cover for blocking the ultraviolet rays, and thus an increase in the number of components and the complexity of the structure can be reduced or prevented as compared with a case in which a cover is separately provided to block the ultraviolet rays.

The expanding device according to the first aspect preferably further includes a notifier to notify a user of an abnormality in the expanded state of the wafer based on an imaging result of the expanded state of the wafer by the imager. Accordingly, the user can be caused to recognize the abnormality in the expanded state of the wafer, and thus the user can be prompted to improve the abnormality in the expanded state of the wafer.

The expanding device according to the first aspect preferably further includes a clamp movement mechanism to move the clamp unit in an upward-downward direction, the expanding device is preferably operable to expand the sheet member by moving down the clamp unit using the clamp movement mechanism while an upper end of the expanding ring is located at a predetermined height position in the upward-downward direction, and the imager is preferably operable to image the expanded state of the wafer by the expanding ring with the upper end located at the predetermined height position. Accordingly, the wafer in the expanded state is maintained at the predetermined height position, and thus when the expanded state of the wafer is imaged by the imager, the focus of the imager can be prevented from shifting from the wafer. Consequently, it is possible to prevent an unclear portion from occurring in an image showing the expanded state of the wafer captured by the imager.

The expanding device according to the first aspect preferably further includes a squeegee unit at a position in a downward direction with respect to the imager to locally press the wafer from below after the sheet member is expanded by the expanding ring, and the imager is preferably operable to capture images before and after the squeegee unit locally presses the wafer after the sheet member is expanded by the expanding ring. Accordingly, the number of semiconductor chips separated by the pressing of the squeegee unit can be acquired from the captured image captured by the imager before the squeegee unit locally presses the wafer and the captured image captured by the imager after the squeegee unit locally presses the wafer.

A semiconductor chip manufacturing method according to a second aspect of the present disclosure includes forming a modified layer in a wafer including a plurality of semiconductor chips by emitting a laser beam to the wafer from a laser irradiator operable to emit the laser beam, and imaging, by an imager, an expanded state of the wafer by an expanding ring at a plurality of timings from a start of expansion of an elastic sheet member to which the wafer has been attached to an end of expansion of the sheet member while the expanding ring divides the wafer into the plurality of individual semiconductor chips by expanding the sheet member in a state in which a clamp unit operable to hold a wafer ring structure including the sheet member holds the wafer ring structure.

As described above, the semiconductor chip manufacturing method according to the second aspect of the present disclosure includes imaging, by the imager, the expanded state of the wafer by the expanding ring at the plurality of timings from the start of expansion of the sheet member to the end of expansion of the sheet member. Accordingly, the expanded state (divided state) of the wafer near the end of expansion can be acquired based on an image captured at a timing near the end of expansion among the plurality of timings of imaging by the imager, and thus it is possible to detect whether or not the plurality of separated semiconductor chips have been separated near the end of expansion. When the plurality of semiconductor chips have been separated near the end of expansion of the sheet member, it is highly likely that the wafer will not be divided into the plurality of semiconductor chips due to a slight change such as the same sheet member being slightly softer or a modified layer of the wafer being formed a little smaller at the next or subsequent expansion of the sheet member. In this regard, according to the present disclosure, the expanded state (divided state) of the wafer near the end of expansion of the sheet member is acquired such that it is possible to acquire an event that is considered to be highly likely to prevent the wafer from being divided into the plurality of chips. Consequently, it is possible to acquire an event that is predicted to prevent the wafer from being divided into the plurality of semiconductor chips, and thus it is possible to obtain the semiconductor chip manufacturing method that can prevent the possibility that the wafer will not be divided into the plurality of semiconductor chips.

A semiconductor chip according to a third aspect of the present disclosure is manufactured by an expanding device including a clamp unit to hold a wafer ring structure including an elastic sheet member to which a wafer to be divided along a dividing line into a plurality of semiconductor chips has been attached, an expanding ring to divide the wafer into the plurality of semiconductor chips spaced apart from each other by expanding the sheet member while the clamp unit holds the wafer ring structure, and an imager to image an expanded state of the wafer by the expanding ring at a plurality of timings from a start of expansion of the sheet member to an end of expansion of the sheet member.

As described above, the semiconductor chip according to the third aspect of the present disclosure is manufactured by the expanding device including the imager to image the expanded state of the wafer by the expanding ring at the plurality of timings from the start of expansion of the sheet member to the end of expansion of the sheet member. Accordingly, the expanded state (divided state) of the wafer near the end of expansion can be acquired based on an image captured at a timing near the end of expansion among the plurality of timings of imaging by the imager, and thus it is possible to detect whether or not the plurality of separated semiconductor chips have been separated near the end of expansion. When the plurality of semiconductor chips have been separated near the end of expansion of the sheet member, it is highly likely that the wafer will not be divided into the plurality of semiconductor chips due to a slight change such as the same sheet member being slightly softer or a modified layer of the wafer being formed a little smaller at the next or subsequent expansion of the sheet member. In this regard, according to the present disclosure, the expanded state (divided state) of the wafer near the end of expansion of the sheet member is acquired such that it is possible to acquire an event that is considered to be highly likely to prevent the wafer from being divided into the plurality of chips. Consequently, it is possible to acquire an event that is predicted to prevent the wafer from being divided into the plurality of semiconductor chips, and thus it is possible to obtain the semiconductor chip that can prevent the possibility that the wafer will not be divided into the plurality of semiconductor chips.

According to the present disclosure, as described above, it is possible to prevent the possibility that the wafer will not be divided into the plurality of chips.

### BRIEF DESCRIPTION OF THE DRAWINGS

FIG. 1 is a plan view showing a semiconductor wafer processing apparatus including a dicing device and an expanding device according to a first embodiment;

FIG. 2 is a plan view showing a wafer ring structure to be processed in the semiconductor wafer processing apparatus according to the first embodiment;

FIG. 3 is a sectional view taken along the line III-III in FIG. 2;

FIG. 4 is a plan view of the dicing device arranged adjacent to the expanding device according to the first embodiment;

FIG. 5 is a side view showing the dicing device arranged adjacent to the expanding device according to the first embodiment, as viewed from the Y2 direction side;

FIG. 6 is a plan view of the expanding device according to the first embodiment;

FIG. 7 is a side view showing the expanding device according to the first embodiment, as viewed from the Y2 direction side;

FIG. 8 is a side view showing the expanding device according to the first embodiment, as viewed from the X1 direction side;

FIG. 9 is a block diagram showing the control configuration of the semiconductor wafer processing apparatus according to the first embodiment;

FIG. 10 is a flowchart of the first half of a semiconductor chip manufacturing process of the semiconductor wafer processing apparatus according to the first embodiment;

FIG. 11 is a flowchart of the second half of the semiconductor chip manufacturing process of the semiconductor wafer processing apparatus according to the first embodiment;

FIG. 12 is a side view showing a state in which a clamp unit is arranged at a raised position in the expanding device according to the first embodiment;

FIG. 13 is a side view a state in which the clamp unit is arranged at a lowered position in the expanding device according to the first embodiment;

FIG. 14 is a side view showing a state in which an ultraviolet irradiator radiates ultraviolet rays in the expanding device according to the first embodiment;

FIG. 15 is a timing chart showing descent of the clamp unit from the raised position to the lowered position and the timing of imaging by an imager in the expanding device according to the first embodiment;

FIG. 16 is a side view showing a state before a moving image is captured by the imager in the expanding device according to the first embodiment;

FIG. 17 is a schematic view showing the state of a wafer before moving image capturing in the expanding device according to the first embodiment;

FIG. 18 is a side view showing an example of a state in the first half of a moving image capturing period by the imager in the expanding device according to the first embodiment;

FIG. 19 is a schematic view showing an example of an image captured by the imager in the first half of the moving image capturing period in the expanding device according to the first embodiment;

FIG. 20 is a side view showing an example of a state in the second half of the moving image capturing period by the imager in the expanding device according to the first embodiment;

FIG. 21 is a schematic view showing an example of an image captured by the imager in the second half of the moving image capturing period in the expanding device according to the first embodiment;

FIG. 22 is a side view showing an example of a state just before the end of the moving image capturing period by the imager in the expanding device according to the first embodiment;

FIG. 23 is a schematic view showing an example of an image captured by the imager just before the end of the moving image capturing period in the expanding device according to the first embodiment;

FIG. 24 is a side view showing an example of a state after moving image capturing by the imager in the expanding device according to the first embodiment;

FIG. 25 is a schematic view showing an example of a post-termination still image captured after moving image capturing by the imager in the expanding device according to the first embodiment;

FIG. 26 is a plan view showing a notifier in the expanding device according to the first embodiment;

FIG. 27 is a schematic view showing a state in which a tensile force is acting on the wafer in the expanding device according to the first embodiment;

FIG. 28 is a schematic view for illustrating that semiconductor chips are separated from an outer portion of the wafer in the expanding device according to the first embodiment;

FIG. 29 is a schematic view showing an example of a state in which the semiconductor chips have been detected by a dicing control calculator in the expanding device according to the first embodiment;

FIG. 30 is a timing chart showing the timing of imaging by the imager in the expanding device according to the first embodiment;

FIG. 31 is a schematic view showing an example in which semiconductor chips are separated from an inner portion of the wafer in the expanding device according to the first embodiment;

FIG. 32 is a schematic view showing an example of a state in which semiconductor chips have been detected in the post-termination still image by the dicing control calculator in the expanding device according to the first embodiment;

FIG. 33 is a flowchart of a wafer imaging process of the semiconductor wafer processing apparatus according to the first embodiment;

FIG. 34 is a plan view showing a semiconductor wafer processing apparatus including a dicing device and an expanding device according to a second embodiment;

FIG. 35 is a side view showing the semiconductor wafer processing apparatus including the dicing device and the expanding device according to the second embodiment, as viewed from the Y2 direction side;

FIG. 36 is a side view showing the semiconductor wafer processing apparatus including the dicing device and the expanding device according to the second embodiment, as viewed from the X1 direction side;

FIG. 37 is a block diagram showing the control configuration of the semiconductor wafer processing apparatus according to the second embodiment;

FIG. 38 is a flowchart of the first half of a semiconductor chip manufacturing process of the semiconductor wafer processing apparatus according to the second embodiment;

FIG. 39 is a flowchart of the second half of the semiconductor chip manufacturing process of the semiconductor wafer processing apparatus according to the second embodiment;

FIG. 40 is a partial sectional view showing an imager and a nitrogen supplier on an expansion maintaining member of an expanding device according to a third embodiment;

FIG. 41 is a plan view showing a state in which a third mounting member of the nitrogen supplier of the expanding device according to the third embodiment has been removed;

FIG. 42 is a plan view showing the third mounting member of the nitrogen supplier of the expanding device according to the third embodiment;

FIG. 43 is a schematic view showing an image captured by an imager before pressing by a squeegee unit in an expanding device according to a modified example of the first to third embodiments; and

FIG. 44 is a schematic view showing an image captured by the imager after pressing by the squeegee unit in the expanding device according to the modified example of the first to third embodiments.

### DETAILED DESCRIPTION

Embodiments embodying the present disclosure are hereinafter described on the basis of the drawings.

### First Embodiment

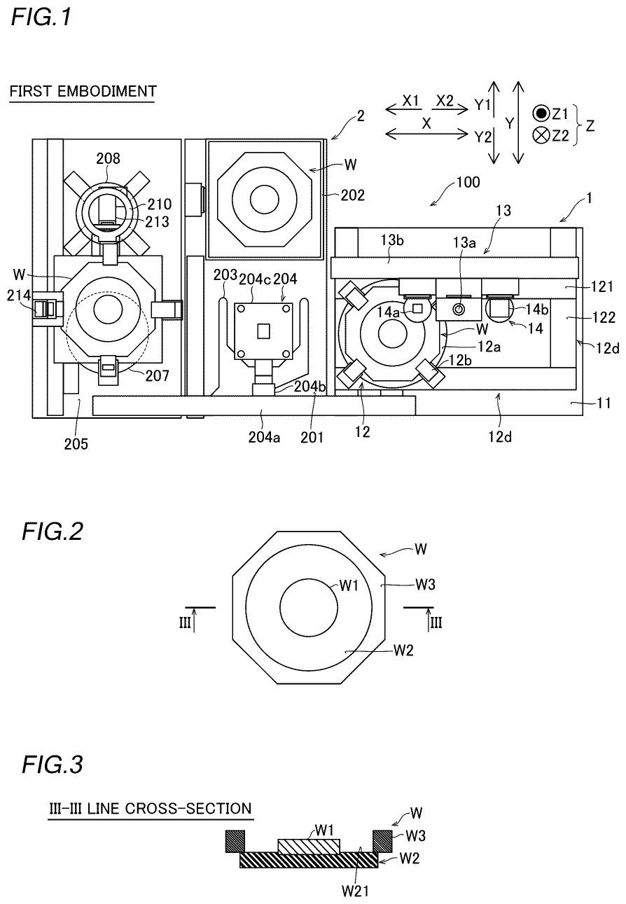

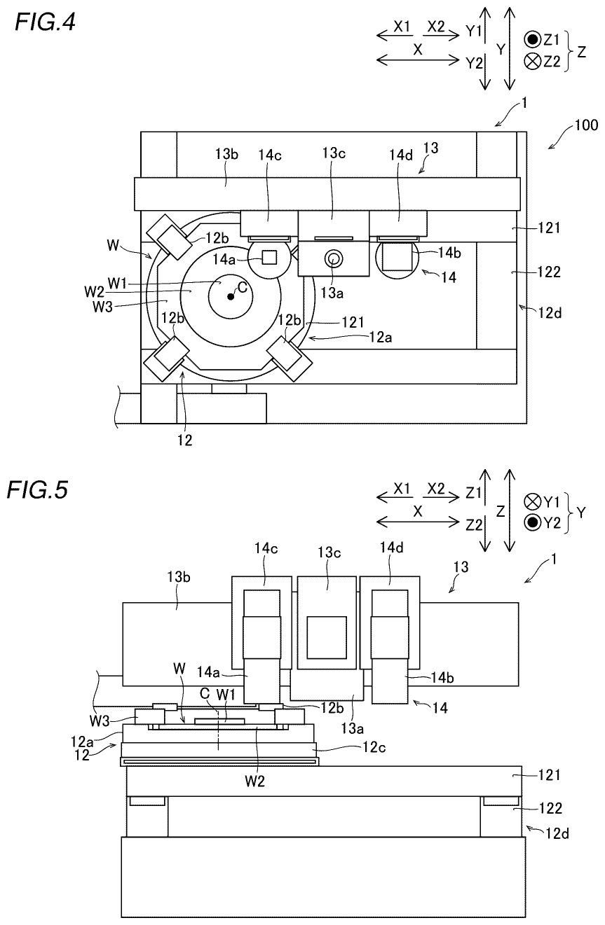

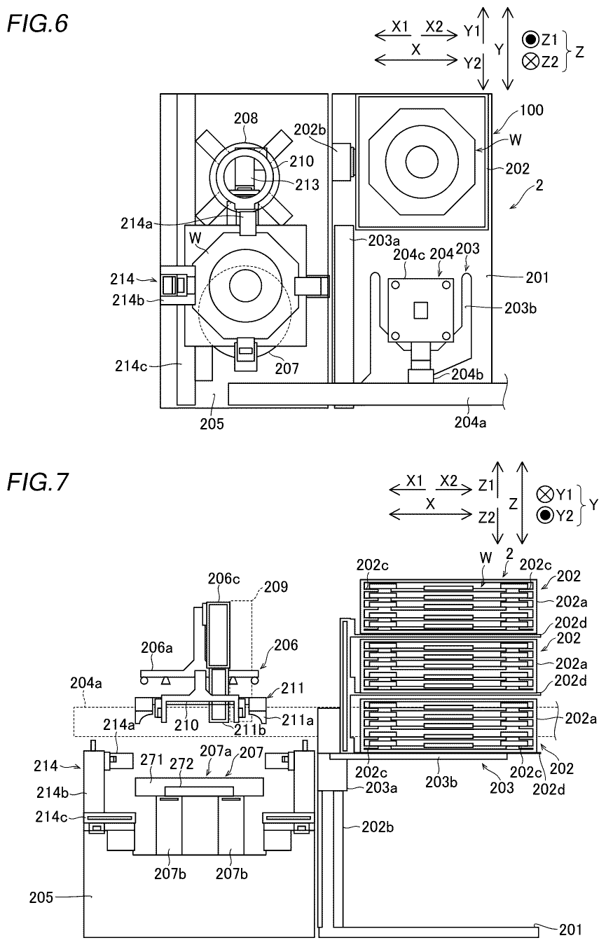

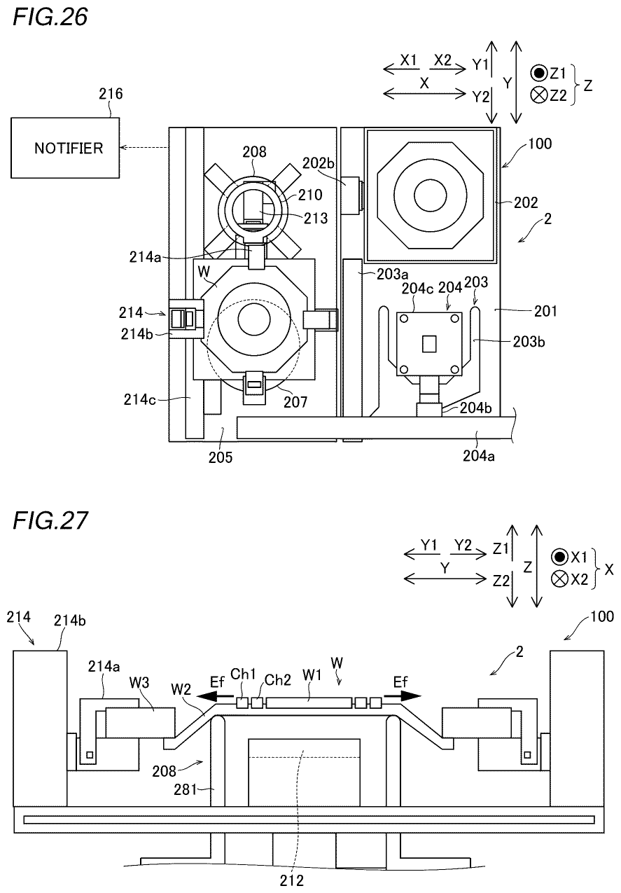

The configuration of a semiconductor wafer processing apparatus 100 according to a first embodiment of the present disclosure is now described with reference to FIGS. 1 to 33.

### Semiconductor Wafer Processing Apparatus

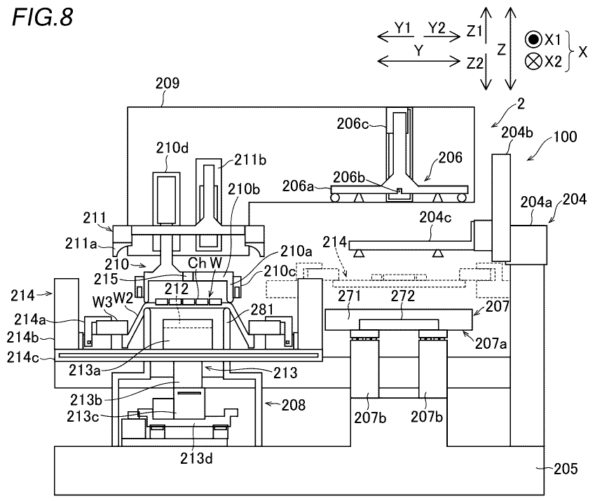

As shown in FIG. 1, the semiconductor wafer processing apparatus 100 is an apparatus that processes a wafer W1 provided on a wafer ring structure W. The semiconductor wafer processing apparatus 100 forms a modified layer in the wafer W1 and divides the wafer W1 along the modified layer to form a plurality of semiconductor chips Ch (see FIG. 8).

The wafer ring structure W is now described with reference to FIGS. 2 and 3. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer is formed by modifying the inside along a dividing line by processing in the semiconductor wafer processing apparatus 100. That is, the wafer W1 is processed so as to be divisible along the dividing line. The sheet member W2 is an elastic adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1.

The semiconductor wafer processing apparatus 100 includes a dicing device 1 and an expanding device 2. Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIGS. 1, 4, and 5, the dicing device 1 emits a laser having a wavelength transmissive to the wafer W1 along the dividing line (street) to form the modified layer. The modified layer refers to a crack, a void, or the like formed inside the wafer W1 by the laser. A method for forming the modified layer in the wafer W1 in this manner is called dicing.

Specifically, the dicing device 1 includes a base 11, a chuck table unit 12, a laser 13, and an imager 14.

The base 11 is a base on which the chuck table unit 12 is installed. The base 11 has a rectangular shape in the plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits a laser beam to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as a laser beam as long as a modified layer can be formed by multiphoton absorption.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or the Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example.

### Expanding Device

As shown in FIGS. 1, 6, and 7, the expanding device 2 divides the wafer W1 to form the plurality of semiconductor chips Ch (see FIG. 8). The expanding device 2 forms a sufficient gap between the plurality of semiconductor chips Ch. A modified layer is formed in the wafer W1 by emitting a laser having a wavelength transmissive to the wafer W1 along the dividing line (street) in the dicing device 1. In the expanding device 2, the plurality of semiconductor chips Ch are formed by dividing the wafer W1 along the modified layer formed in advance in the dicing device 1.

Therefore, in the expanding device 2, the wafer W1 is divided along the modified layer by expanding the sheet member W2. Furthermore, in the expanding device 2, the gap between the plurality of semiconductor chips Ch formed by division is widened by expanding the sheet member W2.

The expanding device 2 includes a base 201, a cassette unit 202, a lift-up hand unit 203, a suction hand unit 204, a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214.

### Base

The base 201 is a base on which the cassette unit 202 and the lift-up hand unit 203 are installed. The base 201 has a rectangular shape in the plan view.

### Cassette Unit

The cassette unit 202 can accommodate a plurality of wafer ring structures W. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module, or a ball screw and a drive including a motor with an encoder, for example. The Z-direction movement mechanism 202b also includes mounting tables 202d that support the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-Up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module, or a ball screw and a drive including a motor with an encoder, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module, or a ball screw and a drive including a motor with an encoder, for example. The suction hand 204c suctions and supports the ring-shaped member W3 of the wafer ring structure W from the Z1 direction side. The suction hand 204c supports the ring-shaped member W3 of the wafer ring structure W by generating a negative pressure.

### Base

As shown in FIGS. 7 and 8, the base 205 is a base on which the expander 208, the cooling unit 207, the ultraviolet irradiator 212, and the squeegee unit 213 are installed. The base 205 has a rectangular shape in the plan view. In FIG. 8, the clamp unit 214 arranged on the Z1 direction side of the cooling unit 207 is indicated by dotted lines.

### Cool Air Supplier

The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module, or a ball screw and a motor with an encoder, for example.

The cool air supply device is a device that generates cool air. The cool air supply device supplies air cooled by a heat pump, for example. Such a cool air supply device is installed on the base 205. The cool air supplier 206 and the cool air supply device are connected to each other by a hose (not shown).

### Cooling Unit

The cooling unit 207 cools the sheet member W2 from the Z2 direction side.

Specifically, the cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

Specifically, the expander 208 includes an expanding ring 281. The expanding ring 281 expands the sheet member W2 by supporting the sheet member W2 from the Z2 direction side. The expanding ring 281 has a ring shape in the plan view. The structure of the expanding ring 281 is described in detail below.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 holds down the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in the plan view. The lid 210b is provided on the pressing ring 210a to close an opening of the pressing ring 210a. The intake 210c is an intake ring having a ring shape in the plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is held down and a position away from the sheet member W2. The Z-direction movement mechanism 210d includes a linear conveyor module, or a ball screw and a drive including a motor with an encoder, for example. The Z-direction movement mechanism 210d is an example of a “member movement mechanism” in the claims. The structure of the expansion maintaining member 210 is described in detail below.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in the plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays Ut to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays Ut to the sheet member W2 while moving together with the squeegee unit 213.

### Squeegee Unit

The squeegee unit 213 further divides the wafer W1 along the modified layer by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer by being moved by the rotation mechanism 213d and the X-direction movement mechanism 213c while pressing the wafer W1 from the Z2 direction side via the sheet member W2. The press 213a presses the wafer W1 by being raised to a raised position on the Z1 direction side by the Z-direction movement mechanism 213b to contact the wafer W1 via the sheet member W2. When the press 213a is lowered to a lowered position on the Z2 direction side by the Z-direction movement mechanism 213b, the contact with the wafer W1 is released such that the wafer W1 is no longer pressed. The press 213a is a squeegee.

The press 213a is attached to an end of the Z-direction movement mechanism 213b

on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and holds down the ring-shaped member W3 from the Z1 direction side. Thus, the ring-shaped member W3 is held by the gripper 214a. The gripper 214a is attached to the Z-direction movement mechanism 214b. The Z-direction movement mechanism 214b is an example of a “clamp movement mechanism” in the claims.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

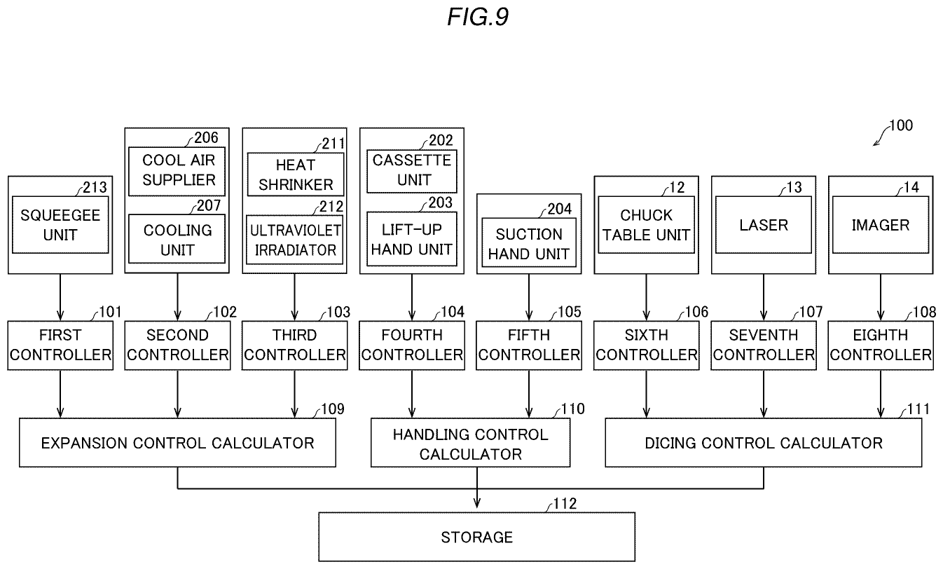

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, a dicing control calculator 111, and a storage 112.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example. The configuration of the expansion control calculator 109 is described in detail below.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example.

The storage 112 stores programs for operating the dicing device 1 and the expanding device 2. The storage 112 includes a ROM, a RAM, and an HDD, for example.

### Semiconductor Chip Manufacturing Process

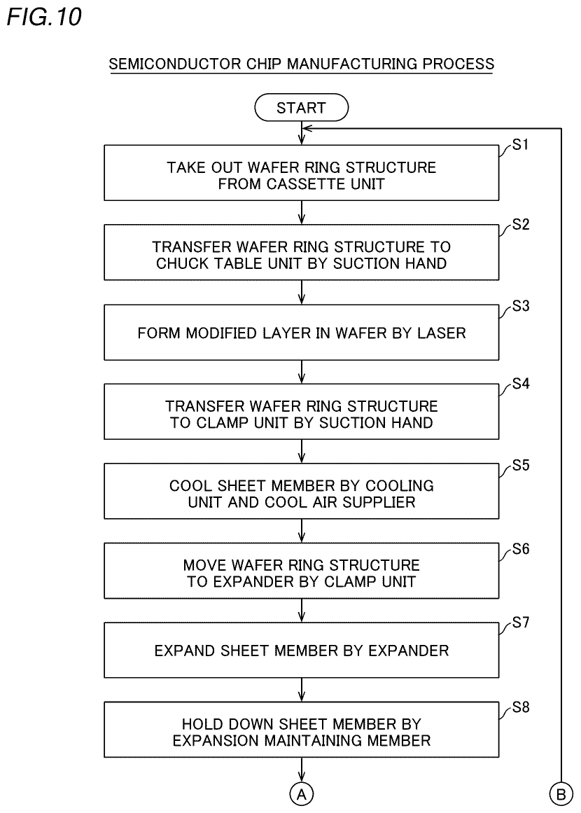

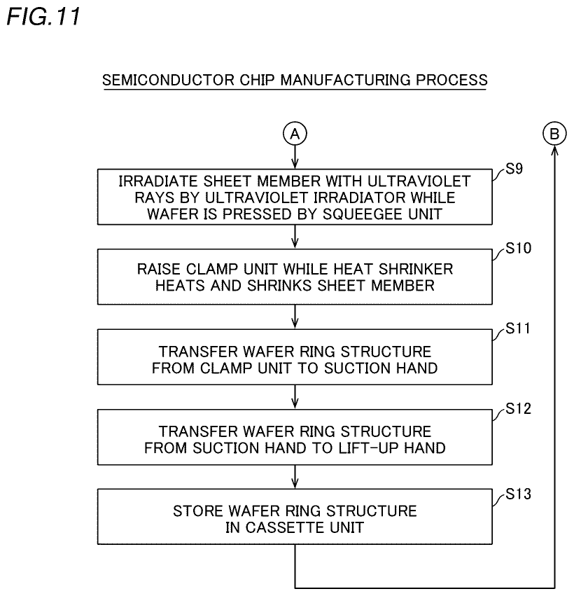

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 203a such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer is formed in the wafer W1 by the laser 13. In step S4, the wafer ring structure W including the wafer W1 in which the modified layer has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer).

In step S8, the expanded sheet member W2 is held down from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is held down by the expansion maintaining member 210, the sheet member W2 is irradiated with ultraviolet rays Ut by the ultraviolet irradiator 212 while the wafer W1 is pressed by the squeegee unit 213. Thus, the wafer W1 is further divided by the squeegee unit 213. In addition, the adhesive strength of the sheet member W2 is reduced by the ultraviolet rays Ut emitted from the ultraviolet irradiator 212.

In step S10, while the heat shrinker 211 heats and shrinks the sheet member W2, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Detailed Configuration of Expander, Expansion Maintaining Member, Ultraviolet Irradiator, and Squeegee Unit

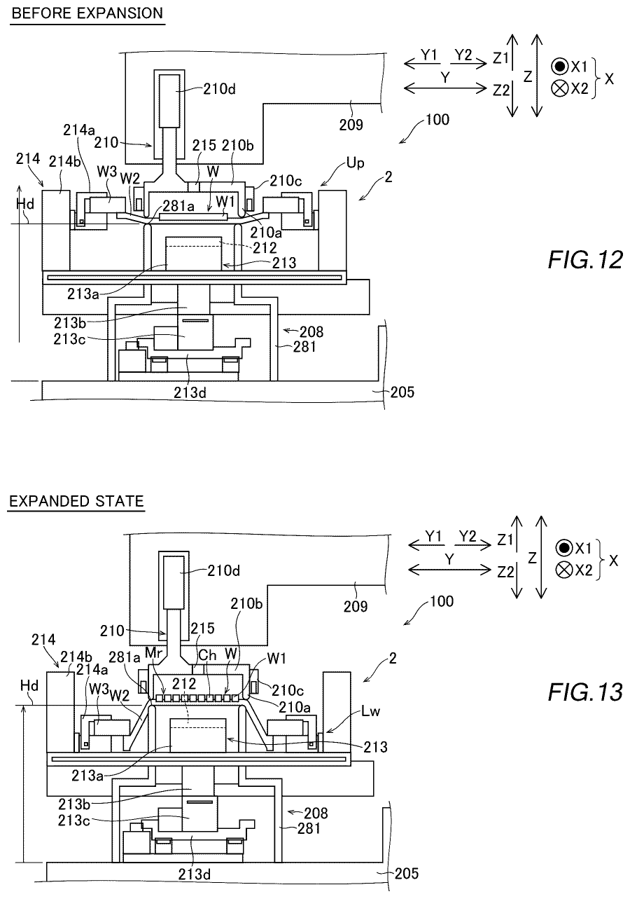

The detailed configuration of the expander 208, the expansion maintaining member 210, the ultraviolet irradiator 212, and the squeegee unit 213 is now described with reference to FIGS. 12 and 13. In FIG. 12, the heat shrinker 211 of the expanding device 2 is not illustrated for convenience.

FIG. 12 shows the state of the expanding device 2 before the sheet member W2 is expanded by the expanding ring 281. The clamp unit 214 is arranged at a raised position Up. That is, the gripper 214a is arranged at the raised position Up by the Z-direction movement mechanism 214b.

FIG. 13 shows the state of the expanding device 2 in which the sheet member W2 is being expanded by the expanding ring 281. The clamp unit 214 is arranged at a lowered position Lw. That is, the gripper 214a is moved in the Z2 direction from the raised position Up toward the lowered position Lw by the Z-direction movement mechanism 214b.

The sheet member W2 is expanded by contacting an upper end 281a of the expanding ring 281 when the gripper 214a is moved in the Z2 direction from the raised position Up toward the lowered position Lw. At this time, the wafer W1 is pulled by the sheet member W2 such that a tensile stress is generated in the wafer W1, and thus the wafer W1 is divided along the modified layer formed in the wafer W1. Thus, the plurality of semiconductor chips Ch are formed.

### Expander

The expander 208 includes the expanding ring 281 that divides the wafer W1 into the plurality of semiconductor chips Ch spaced apart from each other by an interval Mr by expanding the sheet member W2 while the clamp unit 214 holds the wafer ring structure W. That is, the expanding ring 281 expands the sheet member W2 by the clamp unit 214 moved in the Z2 direction from the raised position Up toward the lowered position Lw by the Z-direction movement mechanism 214b.

The expanding ring 281 is fixed on the base 205. The upper end 281a of the expanding ring 281 is arranged at a predetermined height position Hd in the Z direction. The predetermined height position Hd is a height position with the upper surface of the base 205 as a reference. In this manner, the upper end 281a of the expanding ring 281 is maintained at the predetermined height position Hd.

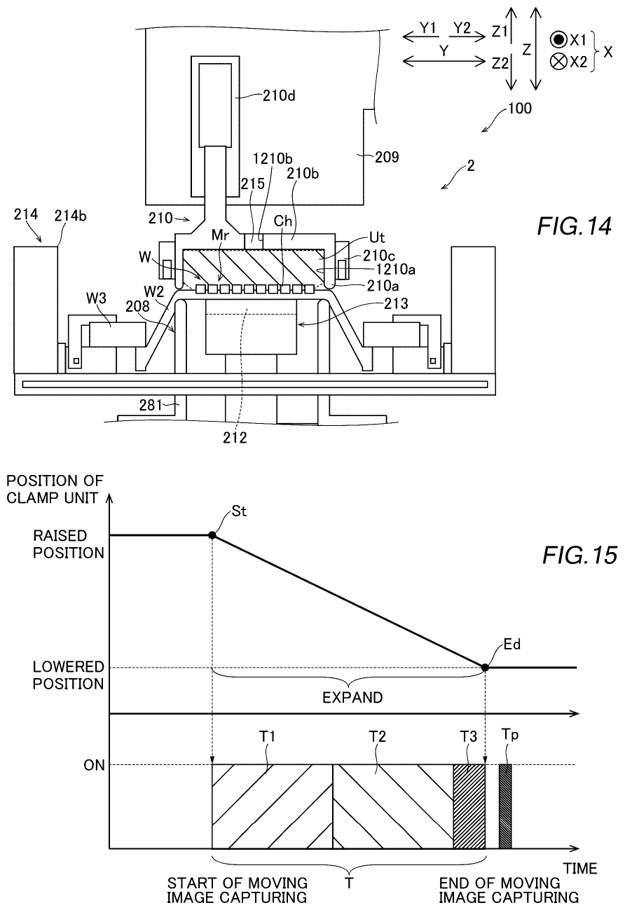

As shown in FIG. 14, the expansion maintaining member 210 maintains the expanded state of the sheet member W2 in the vicinity of the wafer W1. In FIG. 14, the heat shrinker 211 of the expanding device 2 is not illustrated for convenience.

Specifically, the expansion maintaining member 210 includes the pressing ring 210a and the lid 210b.

The pressing ring 210a has a cylindrical shape surrounding the wafer W1 in a plan view. The lid 210b covers the opening of the pressing ring 210a that opens in the Z1 direction. The lid 210b is provided on the inner side 1210a of the pressing ring 210a to close the opening of the pressing ring 210a that opens in the Z1 direction. The lid 210b is provided at an end of the inner side 1210a of the pressing ring 210a on the Z1 direction side. The inner side 1210a is the inner side of the cylindrical pressing ring 210a in the radial direction.

The lid 210b includes a through-hole 1210b penetrating in the Z direction. The through-hole 1210b is provided in a central portion of the lid 210b in the radial direction of the pressing ring 210a. An imager 215 is attached to the through-hole 1210b so as to close the through-hole 1210b.

The ultraviolet irradiator 212 emits ultraviolet rays Ut to the sheet member W2 in the expanded state from the Z2 direction side. The ultraviolet irradiator 212 is at a position in the Z2 direction with respect to the imager 215. The ultraviolet irradiator 212 is at a position in the Z2 direction with respect to the wafer W1 of the sheet member W2 in the expanded state.

The cylindrical pressing ring 210a and the lid 210b cover the wafer W1 from the Z1 direction side to prevent the ultraviolet rays Ut emitted from the ultraviolet irradiator 212 from leaking to the outside from the expansion maintaining member 210. Thus, the expansion maintaining member 210 has not only a function of maintaining the expanded state of the sheet member W2 in the vicinity of the wafer W1, but also a function of shielding the ultraviolet rays Ut. The expansion maintaining member 210 is made of metal such as stainless steel in order to reduce or prevent a deterioration of the material caused by shielding the ultraviolet rays Ut.

### Imager and Notifier

The expanding device 2 according to the first embodiment includes the imager 215 and a notifier 216.

### Imager

The imager 215 images the expanded state of the wafer W1 of the wafer ring structure W held by the clamp unit 214. That is, the imager 215 images the expanded state (divided state) of the wafer W1 by the expanding ring 281 with the upper end 281a located at the predetermined height position Hd (see FIG. 13).

The imager 215 is a wide-angle camera having an angle of view to enable imaging of the entire wafer W1 in the expanded state from the Z1 direction side. The imager 215 includes a plurality of illuminators (not shown). The plurality of illuminators illuminate the wafer W1 in a space covered by the expansion maintaining member 210 when the expansion maintaining member 210 covers the wafer W1 from the Z1 direction side. The space is a space surrounded by the sheet member W2 and the wafer W1 in the expanded state and the expansion maintaining member 210. Thus, the imager 215 images the expanded state of the wafer W1 by the expanding ring 281 in a state in which the expansion maintaining member 210 lowered by the Z-direction movement mechanism 210d covers the wafer W1.

The imager 215 is attached to the expansion maintaining member 210. Specifically, the imager 215 is attached to the lid 210b of the expansion maintaining member 210. The imager 215 is arranged in the central portion of the lid 210b in the radial direction of the pressing ring 210a. The radial direction of the pressing ring 210a is substantially perpendicular to the Z direction.

As shown in FIG. 15, the imager 215 images the expanded state of the wafer W1 by the expanding ring 281 at a plurality of timings from the expansion start time St to the expansion end time Ed of the sheet member W2. FIG. 15 is a timing chart showing an example of an imaging process by the imager 215.

Specifically, the imager 215 captures a moving image including a plurality of captured images obtained by imaging the expanded state (divided state) of the wafer W1 by the expanding ring 281 at a plurality of consecutive timings from the expansion start time St to the expansion end time Ed of the sheet member W2. For example, when the time required for the expanding ring 281 to expand the wafer W1 is about 0.1 to 2 seconds, the imager 215 captures a moving image at about 100 fps. The frame rate of the moving image captured by the imager 215 is set in advance by a user.

The imager 215 starts to capture a moving image of the expanded state of the wafer W1 when the clamp unit 214 starts to descend from the raised position Up, and terminates capturing of a moving image of the expanded state of the wafer W1 when the clamp unit 214 reaches the lowered position Lw.

The imager 215 captures a still image of the semiconductor chips Ch separated from the wafer W1 after terminating capturing of a moving image of the expanded state of the wafer W1.

Thus, the image capturing process by the imager 215 is performed during a moving image capturing period T and at the time after the end of moving image capturing Tp. The time before the start of moving image capturing refers to the time immediately before the clamp unit 214 starts to descend from the raised position Up. The moving image capturing period T refers to a period of time from the time at which the clamp unit 214 starts to descend from the raised position Up to the time at which the clamp unit 214 reaches the lowered position Lw. The time after the end of moving image capturing Tp refers to the time immediately after the clamp unit 214 reaches the lowered position Lw.

The moving image capturing period T can be divided into a first half T1, a second half T2, and a final part T3, for example. The first half T1 is a period of time during the moving image capturing period T that precedes the second half T2 and the final part T3. The second half T2 is a period of time between the first half T1 and the second half T2 during the moving image capturing period T. The final part T3 is a period of time during the moving image capturing period T that follows the second half T2.

The imaging process by the imager 215 in each of the first half T1, the second half T2, and the final part T3 and at the time after the end of moving image capturing Tp is now described with reference to FIGS. 15 to 25.

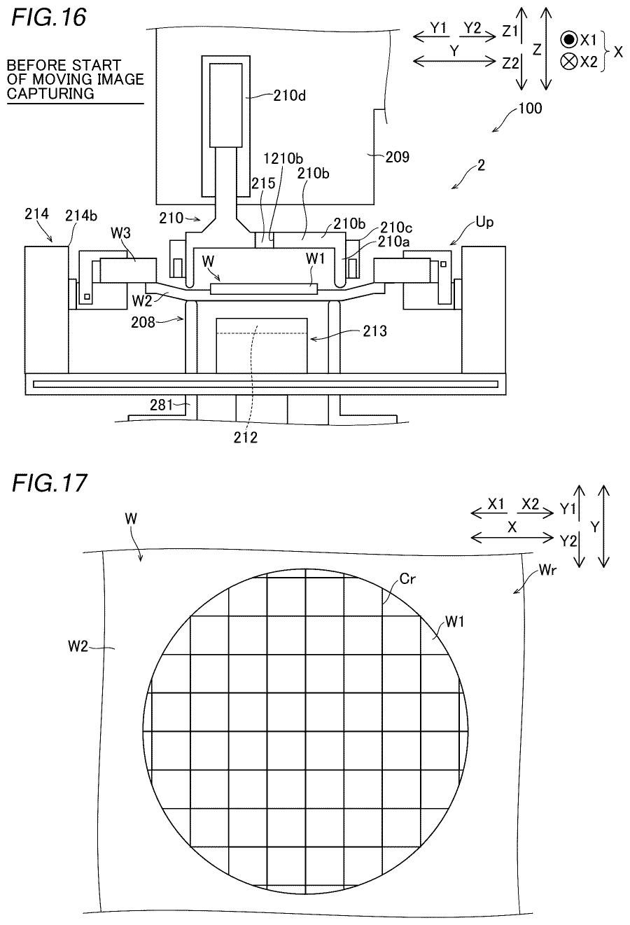

As shown in FIGS. 16 and 17, before the start of moving image capturing, the expanding ring 281 contacts the sheet member W2 in the vicinity of the wafer W1. The expansion maintaining member 210 has moved to an upper position so as not to contact the sheet member W2 contacting the expanding ring 281 in the vicinity of the wafer W1. The upper position is a vicinity on the Z1 direction side with respect to the sheet member W2 contacting the expanding ring 281 in the vicinity of the wafer W1. A crack Cr is formed in the wafer W1 due to the modified layer in the wafer W1.

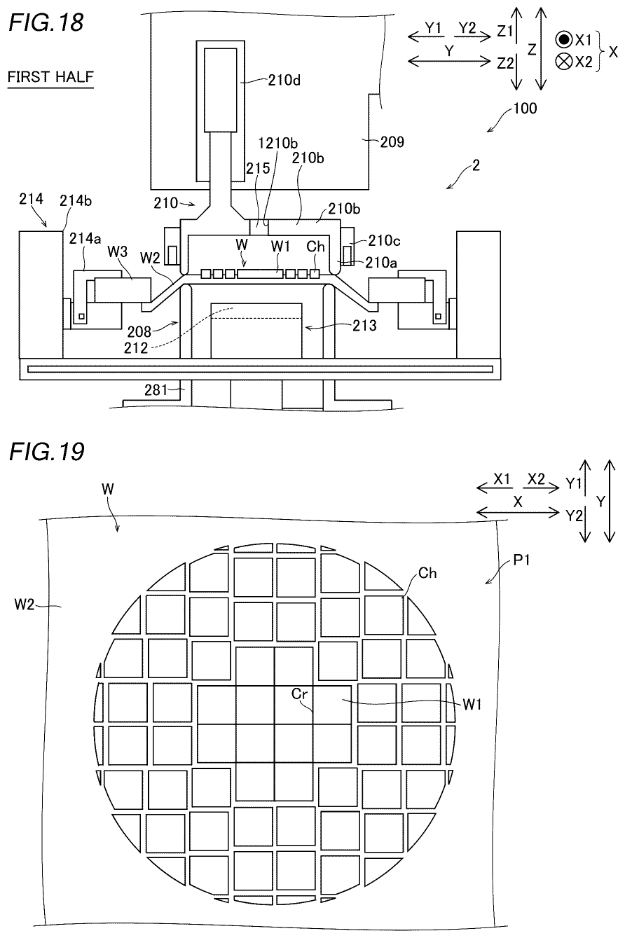

As shown in FIGS. 18 and 19, in the first half T1, a first captured image P1 is captured as one of a plurality of captured images captured in moving image capturing by the imager 215. In the first half T1, the clamp unit 214 is lower than the raised position Up. Thus, a portion of the wafer W1 is divided into a plurality of semiconductor chips Ch due to a tensile stress caused by expansion of the sheet member W2. The portion of the wafer W1 is a portion outside an undivided center portion of the wafer W. The imager 215 captures the first captured image P1 in which the wafer W1 on the center side that remains undivided and the plurality of semiconductor chips Ch formed outside the wafer W1 on the center side appear, as one of the plurality of captured images captured in moving image capturing.

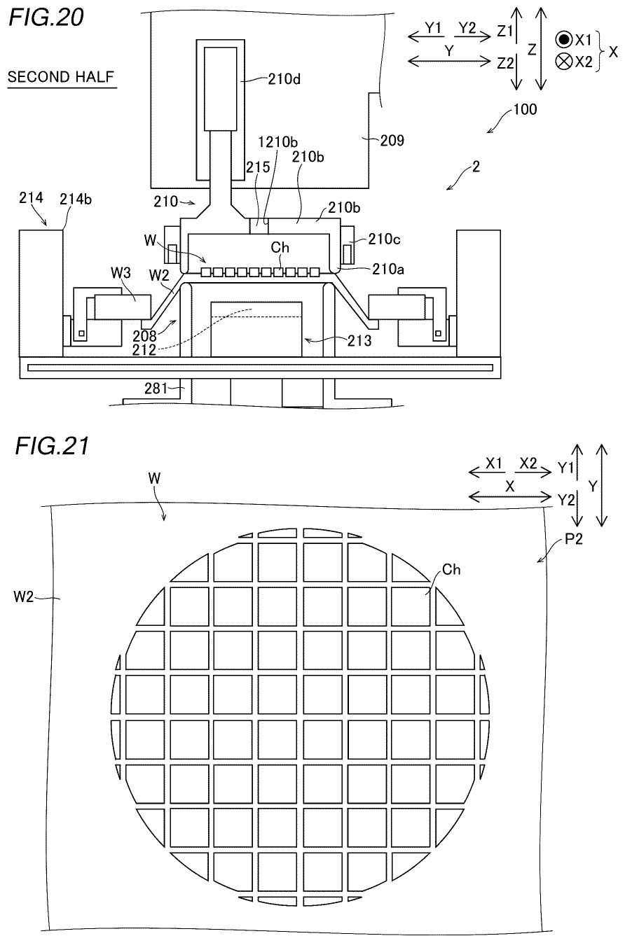

As shown in FIGS. 20 and 21, in the second half T2, a second captured image P2 is captured as one of the plurality of captured images captured in moving image capturing by the imager 215. In the second half T2, the clamp unit 214 is lower than the height position of the clamp unit 214 in the first half T1. Thus, the entire wafer W1 is divided into a plurality of semiconductor chips Ch due to a tensile stress caused by expansion of the sheet member W2. The imager 215 captures the second captured image P2 in which the separated semiconductor chips Ch appear, as one of the plurality of captured images captured in moving image capturing.

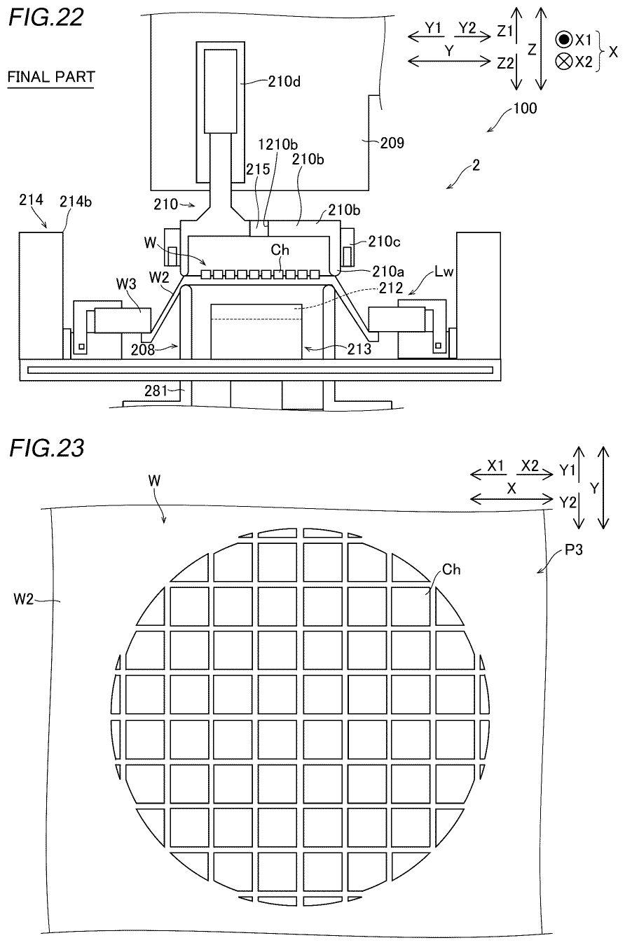

As shown in FIGS. 22 and 23, in the final part T3, a third captured image P3 is captured as one of the plurality of captured images captured in moving image capturing by the imager 215. In the final part T3, the clamp unit 214 is lower than the height position of the clamp unit 214 in the second half part T2. Similarly to the second half T2, the entire wafer W1 is divided into a plurality of semiconductor chips Ch. The imager 215 captures the third captured image P3 in which the separated semiconductor chips Ch appear as one of the plurality of captured images captured in moving image capturing.

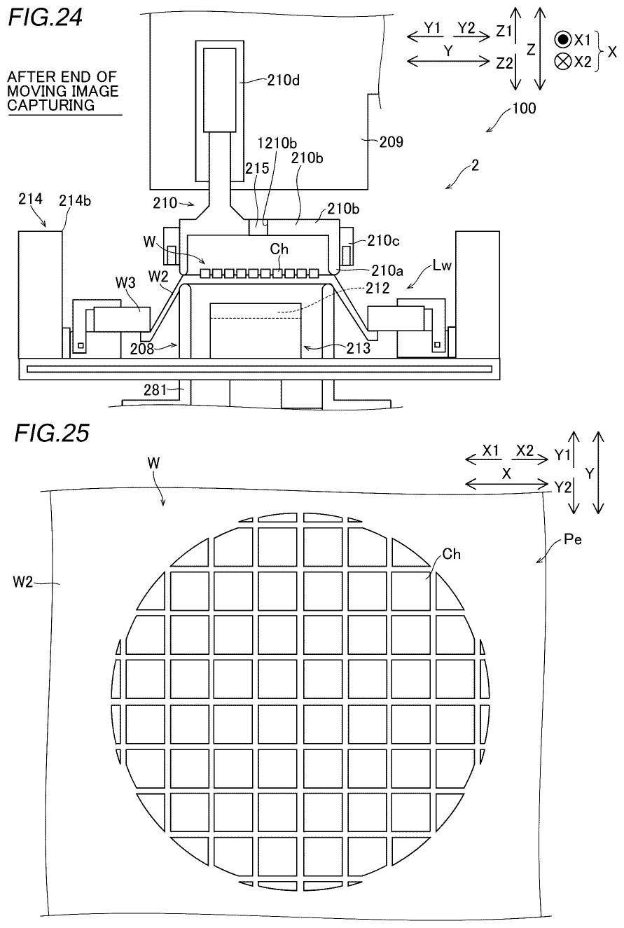

As shown in FIGS. 24 and 25, the imager 215 brings the sheet member W2 in the vicinity of the wafer W1 into contact with the expanding ring 281 at the time after the end of moving image capturing Tp, and images the plurality of semiconductor chips Ch with the sheet member W2 expanded. Thus, a post-termination still image Pe is acquired.

### Notifier

The notifier 216 notifies the user of an abnormality in the expanded state of the wafer W1 based on the imaging results of the expanded state of the wafer W1 by the imager 215. The imaging results refer to the plurality of captured images (such as the first captured image P1, the second captured image P2, and the third captured image P3) captured in moving image capturing by the imager 215.

The notifier 216 includes a display to notify the user of the abnormality in the expanded state of the wafer W1 by displaying the abnormality on a screen. The notifier 216 may be a notifier that notifies the user of the abnormality in the expanded state of the wafer W1 by communication.

### Detailed Configuration of Expansion Control Calculator

In the expanding device 2, the expansion control calculator 109 performs a control to detect the semiconductor chips Ch separated from the wafer W1 based on the plurality of captured images captured in moving image capturing by the imager 215. In other words, the expansion control calculator 109 inspects the timing at which the entire wafer W1 has been divided into a plurality of semiconductor chips Ch when the wafer W1 is expanded, a change in the timing at which the entire wafer W1 has been divided into a plurality of semiconductor chips Ch when the wafer W1 is expanded, and the order in which the wafer W1 has been divided when the wafer W1 is expanded.

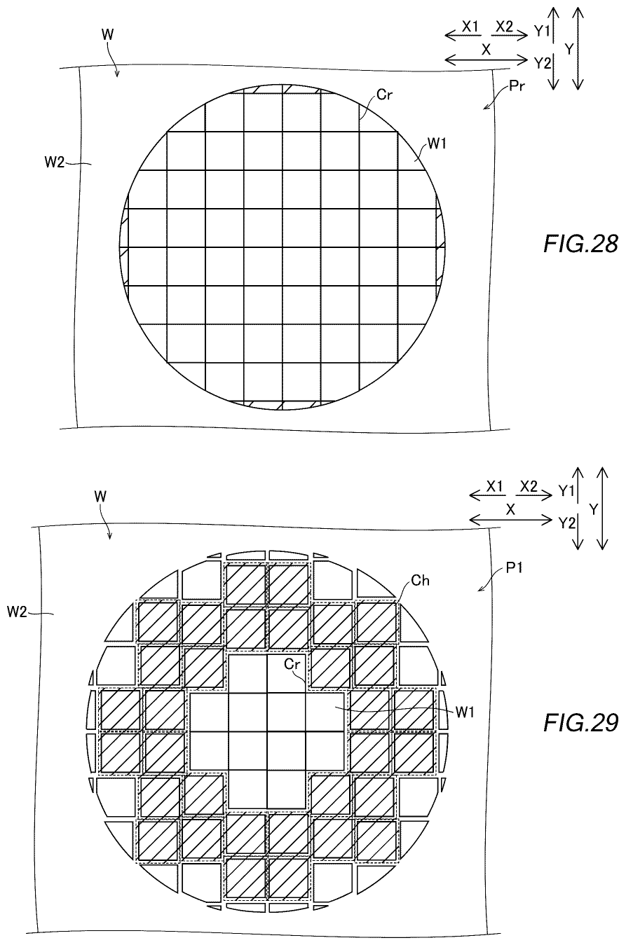

An overview of detecting the separated semiconductor chips Ch based on a plurality of captured images is now described with reference to FIGS. 27 and 28. FIG. 27 illustrates a state in which an outer portion of the wafer W1 is divided into semiconductor chips Ch1, and then a portion of the wafer W1 inside the semiconductor chips Ch1 is divided into semiconductor chips Ch2. FIG. 28 illustrates the wafer W1 before expansion.

In the expansion of the wafer W1, when a dividing force Ef applied to the semiconductor chips Ch1 at the moment at which the semiconductor chips Ch1 are separated is compared with a dividing force Ef applied to the semiconductor chips Ch2 at the moment at which the semiconductor chips Ch2 are separated, the dividing force Ef applied to the semiconductor chips Ch2 is increased by the amount of force of expanding the sheet member W2 increased by descent of the clamp unit 214. However, in such a case, gaps between the semiconductor chips Ch2 and the wafer W1 are increased in addition to gaps between the semiconductor chips Ch1 and the semiconductor chips Ch2, and thus the dividing force Ef applied to the semiconductor chips Ch2 is reduced by the amount of tensile stress on the wafer W1 that has escaped.

As shown in FIG. 28, the length of the dividing line (crack Cr) of the wafer W1 is smaller in the outer portion (shown with hatching) of the wafer W1 than in the inner portion (shown without hatching) of the wafer W1. Furthermore, the number of semiconductor chips Ch to be separated is smaller in the outer portion (shown with hatching) of the wafer W1 than in the inner portion (shown without hatching) of the wafer W1. Thus, when the dividing force Ef is applied to the wafer W1, the outer portion (shown with hatching) of the wafer W1 is more likely to be divided into semiconductor chips Ch than the inner portion (shown without hatching) of the wafer W1, and thus the wafer W1 is divided from the outer portion (shown with hatching) of the wafer W1 toward the inside.

Thus, the separated semiconductor chips Ch are detected such that it is possible to inspect the timing at which the wafer W1 has been divided into the semiconductor chips Ch and whether or not the wafer W1 has been cracked starting from the outer portion (shown with hatching).

### Method for Detecting Separated Semiconductor Chips

As shown in FIG. 29, the expansion control calculator 109 performs a control to detect the semiconductor chip Ch separated from the wafer W1 in each of the plurality of captured images based on the outer shape of the semiconductor chip Ch in a plan view.

In FIG. 29, the first captured image P1 is shown as an example of one of the plurality of captured images. The outer shape in the plan view for detecting the semiconductor chip Ch by the image process is set in advance by the user based on the length in the X direction, the length in the Y direction, and a tolerance (about 5%, for example). In FIG. 29, the outer shape of the semiconductor chip Ch in the plan view is rectangular as an example. When a figure that matches the outer shape of the semiconductor chip Ch in the plan view that is set in advance is detected in the first captured image P1, the expansion control calculator 109 performs a control to detect the figure as the semiconductor chip Ch. The detected semiconductor chip Ch is displayed with rectangular hatching.

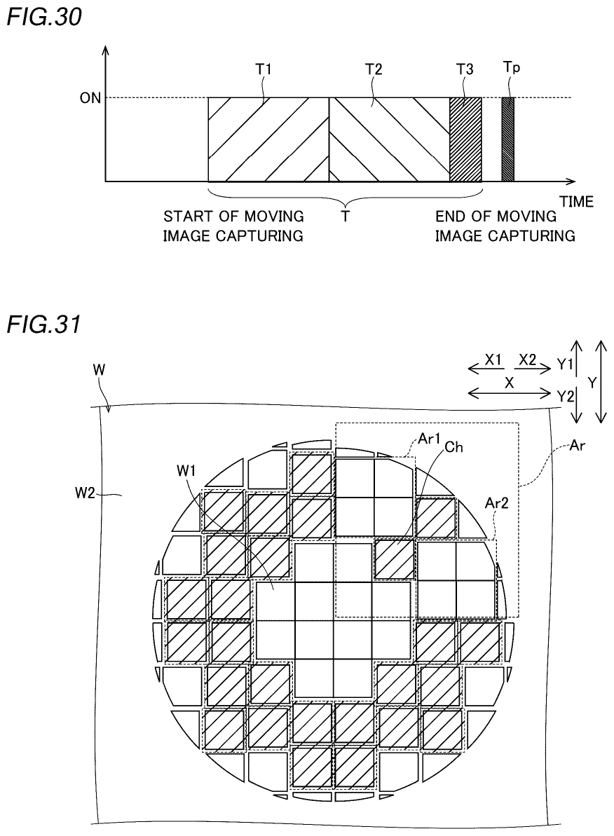

As shown in FIG. 30, the expansion control calculator 109 performs a control to acquire the timing at which the semiconductor chips Ch have been separated based on the semiconductor chips Ch being detected in the plurality of captured images captured in moving image capturing during the moving image capturing period T.

Specifically, the expansion control calculator 109 performs a control to transmit the abnormality in the expanded state to the notifier 216 based on the semiconductor chips Ch being detected in the image (the third captured image P3, for example) captured in the final part T3 among the plurality of captured images. That is, when semiconductor chips Ch are formed by dividing, in the final part T3, a portion of the wafer W1 that has not been divided in the first half T1 and the second half T2, the notifier 216 is notified of the abnormality in the expanded state. Furthermore, the expansion control calculator 109 performs a control to specify the semiconductor chips Ch detected in the image (the third captured image P3, for example) captured in the final part T3, not in the image (the first captured image P1, for example) captured in the first half T1 or the image (the second captured image P2, for example) captured in the second half T2.

In such a case, all the semiconductor chips Ch are separated from the wafer W1, but there is a high possibility that a portion of the wafer W1 is not divided due to the hardness of the sheet member W2, the state of the wafer W1, or a change in room temperature, for example. Therefore, the user is caused to recognize the abnormality in the expanded state by the notifier 216 such that the user can be caused to make a change such as increasing the descent speed of the Z-direction movement mechanism 214b of the clamp unit 214 or lowering the lowered position Lw of the clamp unit 214, for example.

The expansion control calculator 109 performs a control to transmit the abnormality in the expanded state to the notifier 216 based on a difference between the first timing at which the semiconductor chips Ch are detected and the first timing at which the semiconductor chips Ch are detected in the most recent few days. In such a case, the first timing at which the semiconductor chips Ch are detected on the day is in the second half T2, but the first timing at which the semiconductor chips Ch are detected in the most recent few days is in the first half T1, for example. In such a case, there is a high possibility that there is an unexpected change in a lot difference of the sheet material W2 or the temperature in the equipment, for example. Therefore, the notifier 216 causes the user to recognize the abnormality in the expanded state such that the sheet material W2 or the equipment can be inspected.

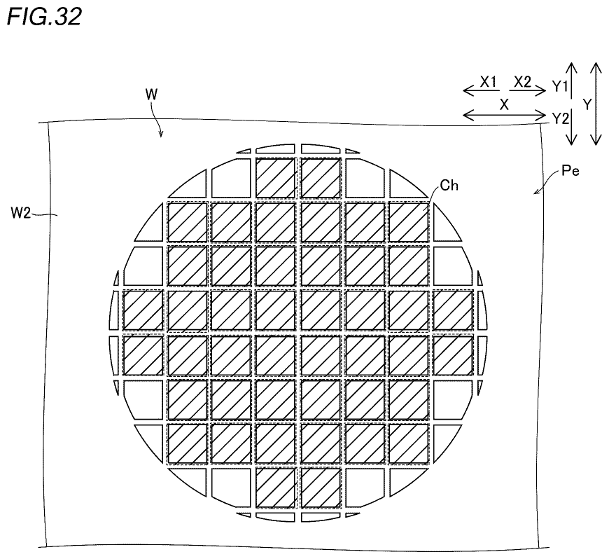

As shown in FIG. 31, the expansion control calculator 109 performs a control to transmit the abnormality in the expanded state to the notifier 216 based on the wafer W1 not being divided from the outer portion of the wafer W1 toward the inside. For example, in an area Ar portion of the captured image, a semiconductor chip Ch separated from the wafer W1 is detected inside the wafer W1 in an area Ar1 and the wafer W1 in an area Ar2. Then, when a semiconductor chip Ch is detected in at least one of the wafer W1 in the area Ar1 or the wafer W1 in the area Ar2 in the next captured image, it is detected that the wafer W1 has not been divided from the outer portion of the wafer W1 toward the inside. In such a case, there is a high possibility that the sheet member W2 is not uniformly expanded, poor attachment of the wafer W1 to the sheet member W2 occurs, or the modified layer formed in the wafer W1 is not uniform. Therefore, the notifier 216 causes the user to recognize the abnormality in the expanded state such that the sheet member W2 or the dicing device 1 can be inspected.

As shown in FIG. 32, the expansion control calculator 109 performs a control to acquire the number of separated semiconductor chips Ch based on the semiconductor chips Ch being detected in the post-termination still image Pe captured at the time after the end of moving image capturing Tp. The expansion control calculator 109 performs a control to identify whether or not separation of the semiconductor chips Ch is good based on the acquired number of separated semiconductor chips Ch. In FIG. 32, the detected semiconductor chips Ch are displayed with rectangular hatching.

### Wafer Imaging Process

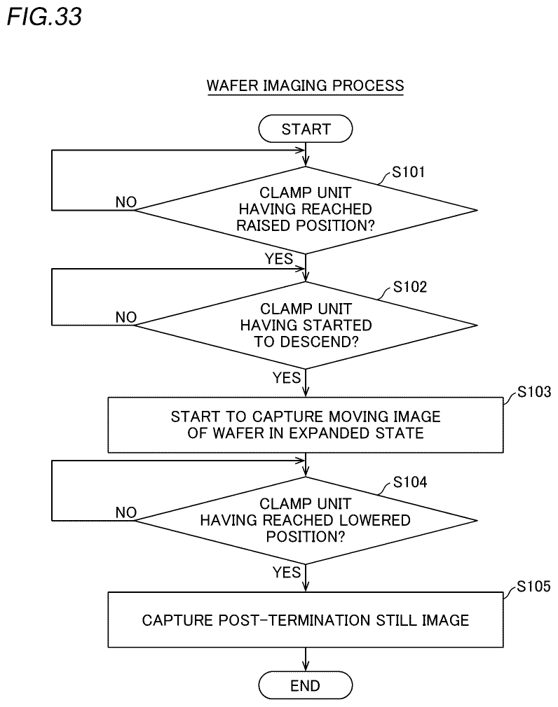

The wafer imaging process using the expansion control calculator 109 and the imager 215 of the semiconductor wafer processing apparatus 100 is now described below with reference to FIG. 33.

In step S101, it is determined whether or not the clamp unit 214 has reached the raised position Up. When the clamp unit 214 has reached the raised position Up, the process advances to step S102, and when the clamp unit 214 has not reached the raised position Up, the process operation in step S101 is repeated. In step S102, it is determined whether or not the clamp unit 214 has started to descend. When the clamp unit 214 has started to descend, the process advances to step S103, and when the clamp unit 214 has not started to descend, the process operation in step S102 is repeated.

In step S103, the imager 215 starts to capture a moving image of the wafer W1 in the expanded state. The clamp unit 214 starts to descend, and thus the sheet member W2 contacting the expanding ring 281 is expanded by the descending clamp unit 214. In step S104, it is determined whether or not the clamp unit 214 has reached the lowered position Lw. When the clamp unit 214 has reached the lowered position Lw, the process advances to step S105. When the clamp unit 214 has not reached the lowered position Lw, the process operation in step S104 is repeated.

In step S105, the post-termination still image Pe is captured by the imager 215, and then the wafer imaging process is terminated.

In a process other than the wafer imaging process in a manufacturing method for the semiconductor chip Ch (semiconductor chip manufacturing process described above), which is a manufacturing method for manufacturing the semiconductor chip Ch, the dicing control calculator 111 performs a step of forming a modified layer in the wafer W1 by emitting a laser beam to the wafer W1 including the plurality of semiconductor chips Ch from the laser irradiator 13a that emits the laser beam. Furthermore, the expansion control calculator 109 performs a step of imaging, by the imager 215, the expanded state of the wafer W1 by the expanding ring 281 at the plurality of timings from the start of expansion of the sheet member W2 to the end of expansion of the sheet member W2 while the expanding ring 281 divides the wafer W1 into the plurality of individual semiconductor chips Ch by expanding the sheet member W2 in a state in which the clamp unit 214 operable to hold the wafer ring structure W holds the wafer ring structure W.

The semiconductor chip Ch manufactured by such a manufacturing method for the semiconductor chip Ch is manufactured by the expanding device 2 including the clamp unit 214, the expanding ring 281, and the imager 215.

### Advantageous Effects of First Embodiment

According to the first embodiment, the following advantageous effects are achieved.

According to the first embodiment, as described above, the expanding device 2 includes the imager 215 to image the expanded state of the wafer W1 by the expanding ring 281 at the plurality of timings from the expansion start time St to the expansion end time Ed of the sheet member W2. Accordingly, the expanded state (divided state) of the wafer W1 near the expansion end time Ed can be acquired based on an image captured at a timing near the expansion end time Ed among the plurality of timings of imaging by the imager 215, and thus it is possible to detect whether or not the plurality of separated semiconductor chips Ch have been separated near the expansion end time Ed. When the plurality of semiconductor chips Ch have been separated from the wafer W1 near the end of expansion of the sheet member W2, it is highly likely that the wafer W1 will not be divided into the plurality of semiconductor chips Ch due to a slight change such as the same sheet member W2 being slightly softer or a modified layer of the wafer W1 being formed a little smaller at the next or subsequent expansion of the sheet member W2. In this regard, according to the present disclosure, the expanded state (divided state) of the wafer W1 near the end of expansion of the sheet member W2 is acquired such that it is possible to acquire an event that is considered to be highly likely to prevent the wafer W1 from being divided into the plurality of semiconductor chips Ch. Consequently, it is possible to acquire an event that is predicted to prevent the wafer W1 from being divided into the plurality of semiconductor chips Ch, and thus it is possible to prevent the possibility that the wafer W1 will not be divided into the plurality of semiconductor chips Ch.

According to the first embodiment, as described above, the imager 215 is operable to capture the moving image including the plurality of captured images obtained by imaging the expanded state of the wafer W1 by the expanding ring 281 at the plurality of consecutive timings from the expansion start time St to the expansion end time Ed of the sheet member W2. Accordingly, the moving image including the plurality of captured images is captured by the imager 215 such that the expanded state of the wafer W1 from the expansion start time St to the expansion end time Ed of the sheet member W2 can be reliably and completely acquired, and thus the timing at which the plurality of semiconductor chips Ch have been separated can be accurately acquired.

According to the first embodiment, as described above, the expanding device 2 includes the expansion maintaining member 210 to maintain the expanded state of the sheet member W2 in the vicinity of the wafer W1. The imager 215 is attached to the expansion maintaining member 210. Accordingly, it is not necessary to provide a dedicated mounting member to attach the imager 215 to the expanding device 2, and thus an increase in the number of components of the expanding device 2 and the complexity of the structure can be reduced or prevented.

According to the first embodiment, as described above, the expansion maintaining member 210 includes the cylindrical pressing ring 210a surrounding the wafer W1. The expansion maintaining member 210 includes the lid 210b to cover the upward opening of the pressing ring 210a. The imager 215 is attached to the lid 210b of the expansion maintaining member 210. Accordingly, the lid 210b is provided at a position at which the upward opening of the cylindrical pressing ring 210a surrounding the wafer W1 is covered, and thus the imager 215 can be arranged above the wafer W1. Consequently, the imager 215 images the wafer W1 from above such that it is possible to easily image the plurality of semiconductor chips Ch that are separated and spaced apart from each other.

According to the first embodiment, as described above, the imager 215 is in the central portion of the lid 210b in the radial direction of the pressing ring 210a. Accordingly, the entire wafer W1 surrounded by the cylindrical pressing ring 210a can be easily imaged from above by the imager 215.

According to the first embodiment, as described above, the expanding device 2 includes the Z-direction movement mechanism 210d to move the expansion maintaining member 210 in the upward-downward direction. The imager 215 is operable to image the expanded state of the wafer W1 by the expanding ring 281 in a state in which the expansion maintaining member 210 lowered by the Z-direction movement mechanism 210d covers the wafer W1. Accordingly, the expanded state of the wafer W1 can be imaged by the imager 215 at a closer position, and thus it is possible to acquire an image in which division of the wafer W1 into the plurality of semiconductor chips Ch is more clearly imaged.

According to the first embodiment, as described above, the expanding device 2 includes the ultraviolet irradiator 212 at a position in the Z2 direction with respect to the imager 215 to irradiate the sheet member W2 in the expanded state with ultraviolet rays Ut from below. The expansion maintaining member 210 is operable to cover the wafer W1 from above with the cylindrical pressing ring 210a and the lid 210b such that the ultraviolet rays Ut radiated from the ultraviolet irradiator 212 to the sheet member W2 do not leak from the expansion maintaining member 210 to the outside. Accordingly, the expansion maintaining member 210 can be used not only as a mounting member for the imager 215 but also as a cover for blocking the ultraviolet rays Ut, and thus an increase in the number of components and the complexity of the structure can be reduced or prevented as compared with a case in which a cover is separately provided to block the ultraviolet rays.

According to the first embodiment, as described above, the expanding device 2 includes the notifier 216 to notify the user of the abnormality in the expanded state of the wafer W1 based on the imaging results of the expanded state of the wafer W1 by the imager 215. Accordingly, the user can be caused to recognize the abnormality in the expanded state of the wafer W1, and thus the user can be prompted to improve the abnormality in the expanded state of the wafer W1.

According to the first embodiment, as described above, the expanding device 2 includes the Z-direction movement mechanism 214b to move the clamp unit 214 in the upward-downward direction. In the expanding device 2, the sheet member W2 is expanded by moving down the clamp unit 214 using the Z-direction movement mechanism 214b while the upper end 281a of the expanding ring 281 is located at the predetermined height position Hd in the upward-downward direction. The imager 215 is operable to image the expanded state of the wafer W1 by the expanding ring 281 with the upper end 281a located at the predetermined height position Hd. Accordingly, the wafer W1 in the expanded state is maintained at the predetermined height position Hd, and thus when the expanded state of the wafer W1 is imaged by the imager 215, the focus of the imager 215 can be prevented from shifting from the wafer W1. Consequently, it is possible to prevent an unclear portion from occurring in an image showing the expanded state of the wafer W1 captured by the imager 215.

According to the first embodiment, as described above, the manufacturing method for the semiconductor chip Ch includes a step of imaging, by the imager 215, the expanded state of the wafer W1 by the expanding ring 281 at the plurality of timings from the start of expansion of the sheet member W2 to the end of expansion of the sheet member W2. Accordingly, the expanded state (divided state) of the wafer W1 near the end of expansion can be acquired based on the image captured at the timing near the end of expansion among the plurality of timings of imaging by the imager 215, and thus it is possible to detect whether or not the plurality of separated semiconductor chips Ch have been separated near the end of expansion. When the plurality of semiconductor chips Ch have been separated near the end of expansion of the sheet member W2, it is highly likely that the wafer W1 will not be divided into the plurality of semiconductor chips Ch due to a slight change such as the same sheet member W2 being slightly softer or a modified layer of the wafer W1 being formed a little smaller at the next or subsequent expansion of the sheet member W2. In this regard, according to the present disclosure, the expanded state (divided state) of the wafer W1 near the end of expansion of the sheet member W2 is acquired such that it is possible to acquire an event that is considered to be highly likely to prevent the wafer W1 from being divided into the plurality of chips. Consequently, it is possible to acquire an event that is predicted to prevent the wafer W1 from being divided into the plurality of semiconductor chips Ch, and thus it is possible to obtain the manufacturing method for the semiconductor chip Ch that can prevent the possibility that the wafer W1 will not be divided into the plurality of semiconductor chips Ch.

According to the first embodiment, as described above, the semiconductor chip Ch is manufactured by the expanding device 2 including the imager 215 to image the expanded state of the wafer W1 by the expanding ring 281 at the plurality of timings from the start of expansion of the sheet member W2 to the end of expansion of the sheet member W2. Accordingly, the expanded state (divided state) of the wafer W1 near the end of expansion can be acquired based on the image captured at the timing near the end of expansion among the plurality of timings of imaging by the imager 215, and thus it is possible to detect whether or not the plurality of separated semiconductor chips Ch have been separated near the end of expansion. When the plurality of semiconductor chips Ch have been separated near the end of expansion of the sheet member W2, it is highly likely that the wafer W1 will not be divided into the plurality of semiconductor chips Ch due to a slight change such as the same sheet member W2 being slightly softer or a modified layer of the wafer W1 being formed a little smaller at the next or subsequent expansion of the sheet member W2. In this regard, according to the present disclosure, the expanded state (divided state) of the wafer W1 near the end of expansion of the sheet member W2 is acquired such that it is possible to acquire an event that is considered to be highly likely to prevent the wafer W1 from being divided into the plurality of chips. Consequently, it is possible to acquire an event that is predicted to prevent the wafer W1 from being divided into the plurality of semiconductor chips Ch, and thus it is possible to obtain the semiconductor chip Ch that can prevent the possibility that the wafer W1 will not be divided into the plurality of semiconductor chips Ch.

### Second Embodiment

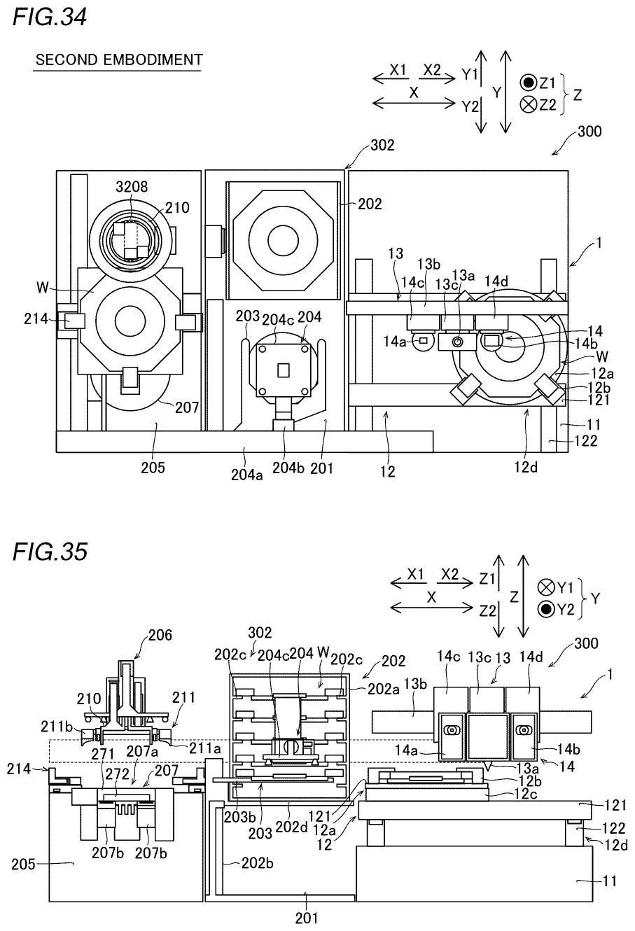

The configuration of a semiconductor wafer processing apparatus 300 according to a second embodiment is now described with reference to FIGS. 34 to 39. In the second embodiment, a squeegee unit 3213 is arranged outside an expanding ring 3281, unlike the first embodiment. In the second embodiment, detailed description of the same or similar configurations as those of the first embodiment is omitted.

### Semiconductor Wafer Processing Apparatus

As shown in FIGS. 34 and 35, the semiconductor wafer processing apparatus 300 is an apparatus that processes a wafer W1 provided on a wafer ring structure W.

The semiconductor wafer processing apparatus 300 includes a dicing device 1 and an expanding device 302. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 302 are aligned is defined as an X direction, a direction from the dicing device 1 toward the expanding device 302 in the X direction is defined as an X1 direction, and a direction from the expanding device 302 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser having a wavelength transmissive to the wafer W1 along a dividing line (street) to form a modified layer.

Specifically, the dicing device 1 includes a base 11, a chuck table unit 12, a laser 13, and an imager 14.

### Expanding Device

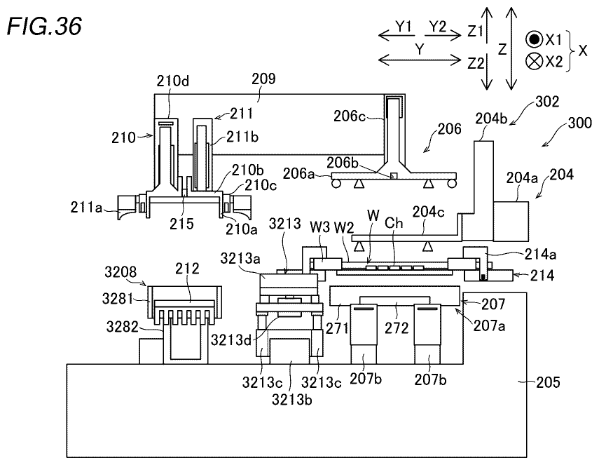

As shown in FIGS. 35 and 36, the expanding device 302 divides the wafer W1 to form a plurality of semiconductor chips Ch.

The expanding device 302 includes a base 201, a cassette unit 202, a lift-up hand unit 203, a suction hand unit 204, a base 205, a cool air supplier 206, a cooling unit 207, an expander 3208, a base 209, an expansion maintaining member 210, a heat shrinker 211, an ultraviolet irradiator 212, a squeegee unit 3213, a clamp unit 214, an imager 215, and a notifier 216.

### Expander

The expander 3208 expands a sheet member W2 of the wafer ring structure W to divide the wafer W1 along the dividing line.

Specifically, the expander 3208 includes the expanding ring 3281 and a Z-direction movement mechanism 3282.

The expanding ring 3281 expands the sheet member W2 by supporting the sheet member W2 from the Z2 direction side. The expanding ring 3281 has a ring shape in a plan view. The Z-direction movement mechanism 3282 moves the expanding ring 3281 in the Z1 direction or the Z2 direction. The Z-direction movement mechanism 3282 includes a linear conveyor module, or a ball screw and a drive including a motor with an encoder, for example. The Z-direction movement mechanism 3282 is attached to the base 205. In the expanded state, an upper end 3281a of the expanding ring 3281 is held at a predetermined height position Hd by the Z-direction movement mechanism 3282.

### Squeegee Unit

The squeegee unit 3213 further divides the wafer W1 along the modified layer by pressing the wafer W1 from the Z2 direction side after the sheet member W2 is expanded. Specifically, the squeegee unit 3213 includes a press 3213a, an X-direction movement mechanism 3213b, a Z-direction movement mechanism 3213c, and a rotation mechanism 3213d.

The prese 3213a generates a bending stress in the wafer W1 to divide the wafer W1 along the modified layer by being moved by the rotation mechanism 3213d and the X-direction movement mechanism 3213b while pressing the wafer W1 from the Z2 direction side via the sheet member W2 after being moved in the Z1 direction by the Z-direction movement mechanism 3213c. The press 3213a is a squeegee. The press 3213a is attached to an end of the rotation mechanism 3213d on the Z1 direction side. The Z-direction movement mechanism 3213c moves the rotation mechanism 3213d in the Z1 direction or the Z2 direction. The Z-direction movement mechanism 3213c includes a cylinder, for example. The Z-direction movement mechanism 3213c is attached to an end of the X-direction movement mechanism 3213b on the Z1 direction side. The X-direction movement mechanism 3213b includes a linear conveyor module, or a ball screw and a drive including a motor with an encoder, for example. The X-direction movement mechanism 3213b is attached to an end of the base 205 on the Z1 direction side.

In the squeegee unit 3213, the prese 3213a divides the wafer W1 by being moved in the Y direction by the X-direction movement mechanism 3213b while pressing the wafer W1 from the Z2 direction side via the sheet member W2 after being moved in the Z1 direction by the Z-direction movement mechanism 3213c. Furthermore, in the squeegee unit 3213, after the press 3213a finishes moving in the Y direction, the press 3213a is rotated 90 degrees by the rotation mechanism 3213d. Moreover, in the squeegee unit 3213, the press 3213a divides the wafer W1 by being moved in the X direction by the X-direction movement mechanism 3213b while pressing the wafer W1 from the Z2 direction side via the sheet member W2 after being rotated 90 degrees.

### Control Configuration of Semiconductor Wafer Processing Apparatus

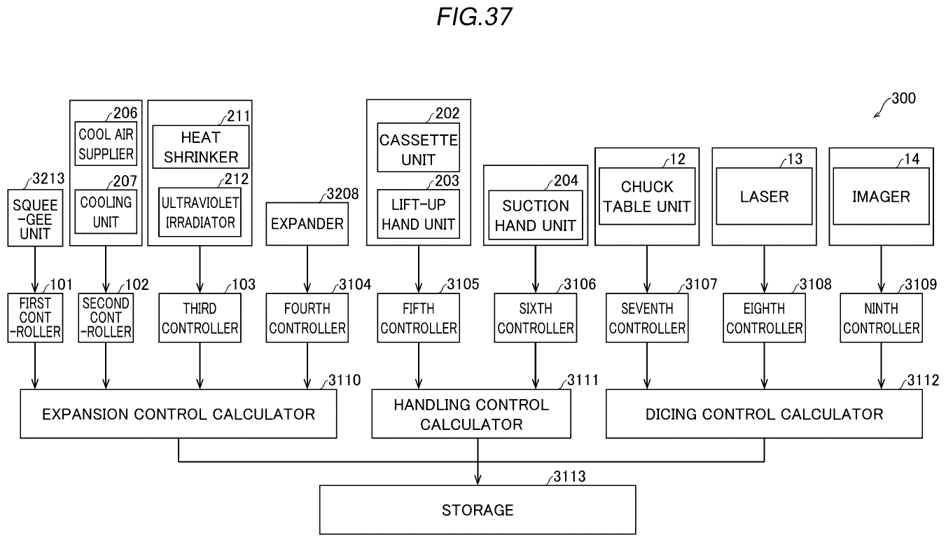

As shown in FIG. 37, the semiconductor wafer processing apparatus 300 includes a first controller 101, a second controller 102, a third controller 103, a fourth controller 3104, a fifth controller 3105, a sixth controller 3106, a seventh controller 3107, an eighth controller 3108, a ninth controller 3109, an expansion control calculator 3110, a handling control calculator 3111, a dicing control calculator 3112, and a storage 3113. The first controller 101, the second controller 102, the third controller 103, the fifth controller 3105, the sixth controller 3106, the seventh controller 3107, the eighth controller 3108, the ninth controller 3109, the expansion control calculator 3110, the handling control calculator 3111, the dicing control calculator 3112, and the storage 3113 have the same configurations as the first controller 101, the second controller 102, the third controller 103, the fourth controller 104, the fifth controller 105, the sixth controller 106, the seventh controller 107, the eighth controller 108, the expansion control calculator 109, the handling control calculator 110, the dicing control calculator 111, and the storage 112 according to the first embodiment, respectively, and thus description thereof is omitted.

The fourth controller 3104 controls the expander 3208. The fourth controller 3104 includes a CPU and a storage including a ROM and a RAM, for example. The fourth controller 3104 may include, as a storage, an HDD that retains stored information even after the voltage is cut off, for example.

### Semiconductor Chip Manufacturing Process

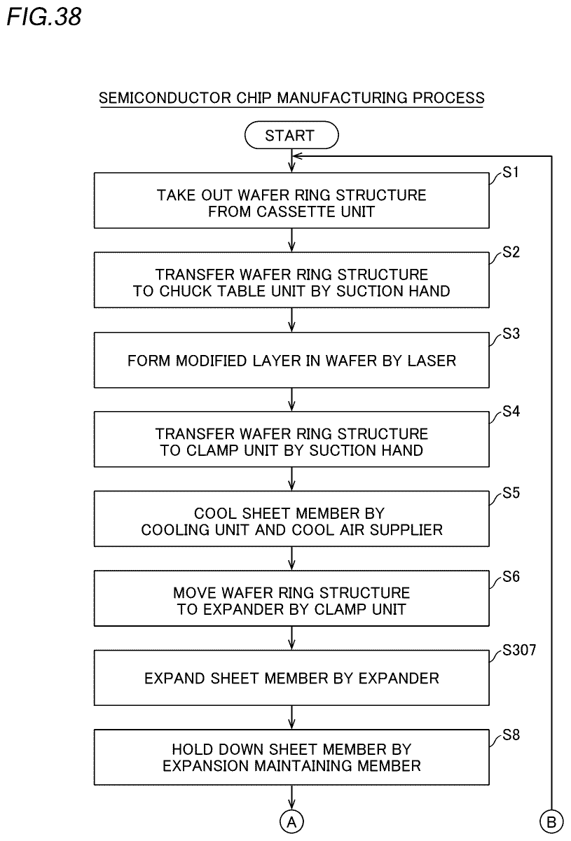

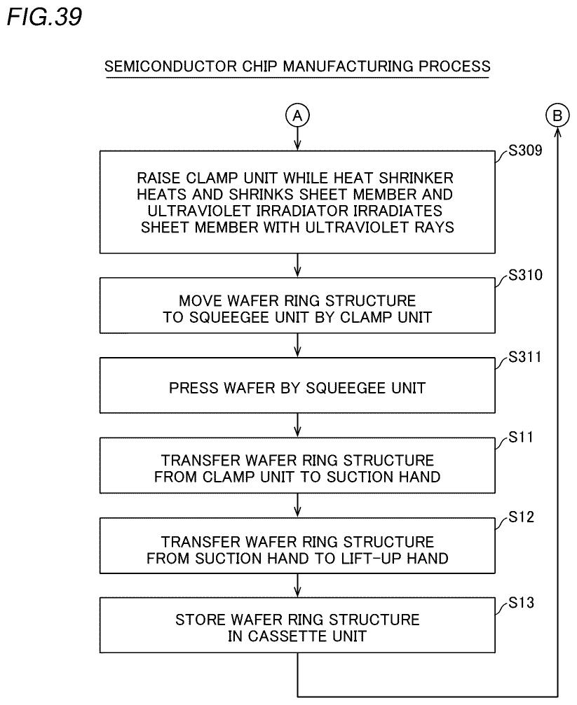

The overall operation of the semiconductor wafer processing apparatus 300 is described below with reference to FIGS. 38 and 39.

Process operations in step S1 to step S6, step S8, and step S11 are the same as the process operations in step S1 to step S6, step S8, and step S11 in the semiconductor chip manufacturing process according to the first embodiment, respectively, and thus description thereof is omitted.

In step S307, the sheet member W2 is expanded by the expander 3208. That is, the expanding ring 3281 is moved in the Z1 direction by the Z-direction movement mechanism 3282. The wafer ring structure W is moved in the Z2 direction by a Z-direction movement mechanism 214b while being held by the clamp unit 214. Then, the sheet member W2 is expanded by contacting the expanding ring 3281 and being pulled by the expanding ring 3281. Thus, the wafer W1 is divided along the dividing line (modified layer).

As shown in FIG. 39, in step S309, while the heat shrinker 211 heats and shrinks the sheet member W2 and the ultraviolet irradiator 212 irradiates the sheet member W2 with ultraviolet rays Ut, the clamp unit 214 is raised. At this time, an intake 210c takes in air in the vicinity of the heated sheet member W2. In step S310, the wafer ring structure W is moved to the squeegee unit 3213 by the clamp unit 214. That is, the wafer ring structure W is moved in the Y2 direction by a Y-direction movement mechanism 214c while being held by the clamp unit 214.

In step S311, after the wafer ring structure W is moved to the squeegee unit 3213, the wafer W1 is pressed by the squeegee unit 3213. Thus, the wafer W1 is further divided by the squeegee unit 3213.

### Detailed Configuration of Expansion Control Calculator

The detailed configuration of the expansion control calculator 3110 is the same as the detailed configuration of the expansion control calculator 109 according to the first embodiment, and thus description thereof is omitted. The remaining configurations of the second embodiment are similar to those of the first embodiment, and thus description thereof is omitted.

### Advantageous Effects of Second Embodiment

According to the second embodiment, the following advantageous effects are achieved.

According to the second embodiment, similarly to the first embodiment, the expanding device 302 includes the imager 215 to image the expanded state of the wafer W1 by the expanding ring 3281 at a plurality of timings from the expansion start time St to the expansion end time Ed of the sheet member W2. Accordingly, it is possible to prevent the possibility that the wafer W1 will not be divided into the plurality of semiconductor chips Ch. The remaining advantageous effects of the second embodiment are similar to those of the first embodiment, and thus description thereof is omitted.

### Third Embodiment

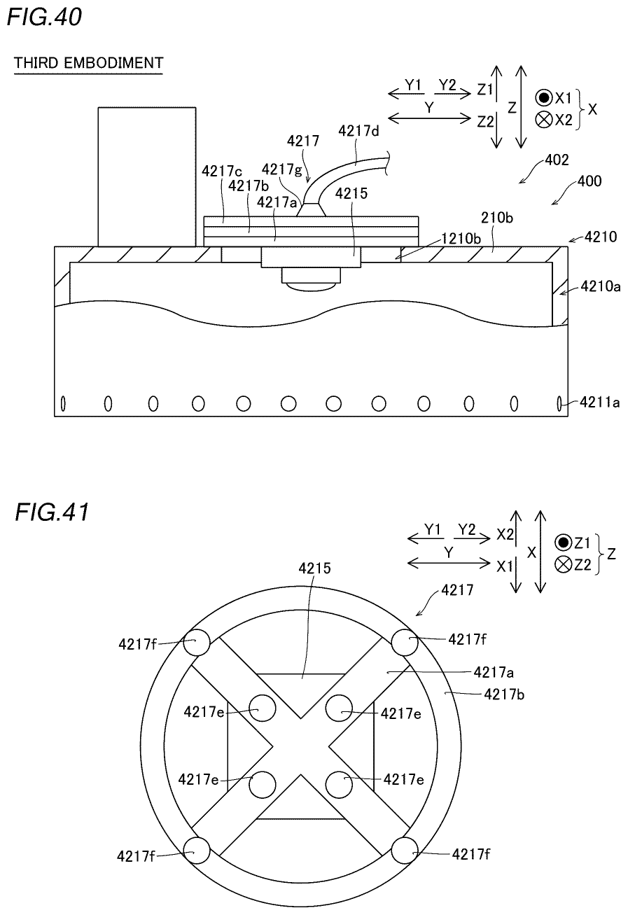

The configuration of a semiconductor wafer processing apparatus 400 according to a third embodiment is now described with reference to FIGS. 40 to 42. In the third embodiment, an expanding device 402 includes both an imager 4215 and a nitrogen supplier 4217, unlike the first embodiment. In the third embodiment, detailed description of the same or similar configurations as those of the first embodiment is omitted.

### Semiconductor Wafer Processing Apparatus

As shown in FIG. 40, the semiconductor wafer processing apparatus 400 is an apparatus that processes a wafer W1 provided on a wafer ring structure W.

The semiconductor wafer processing apparatus 400 includes a dicing device 1 and the expanding device 402. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 402 are aligned is defined as an X direction, a direction from the dicing device 1 toward the expanding device 402 in the X direction is defined as an X1 direction, and a direction from the expanding device 402 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser having a wavelength transmissive to the wafer W1 along a dividing line (street) to form a modified layer.

Specifically, the dicing device 1 includes a base 11, a chuck table unit 12, a laser 13, and an imager 14.

### Expanding Device

As shown in FIGS. 40 and 41, the expanding device 402 divides the wafer W1 to form a plurality of semiconductor chips Ch.

The expanding device 402 includes a base 201, a cassette unit 202, a lift-up hand unit 203, a suction hand unit 204, a base 205, a cool air supplier 206, a cooling unit 207, an expander 208, a base 209, an expansion maintaining member 4210, a heat shrinker 211, an ultraviolet irradiator 212, a squeegee unit 213, a clamp unit 214, the imager 4215, a notifier 216, and the nitrogen supplier 4217.

### Expansion Maintaining Member

As shown in FIG. 40, the expansion maintaining member 4210 includes a pressing ring 4210a and a lid 210b.

The pressing ring 4210a includes an air release hole 4211a. The air release hole 4211a is a hole through which oxygen in the expansion maintaining member 4210 flows out by nitrogen supplied from the nitrogen supplier 4217. The air release hole 4211a penetrates the pressing ring 4210a in the radial direction. The air release hole 4211a is provided on the Z2 direction side with respect to the pressing ring 4210a.

The lid 210b includes a through-hole 1210b penetrating in the Z direction. The through-hole 1210b is provided in a central portion of the lid 210b in the radial direction of the pressing ring 4210a. The imager 4215 is arranged inside the through-hole 1210b. Furthermore, the nitrogen supplier 4217 is attached to an edge of the through-hole 1210b on the Z1 direction side. The through-hole 1210b is covered with the nitrogen supplier 4217.

### Imager

The imager 4215 images the expanded state of the wafer W1 of the wafer ring structure W held by the clamp unit 214. The imager 4215 is a fish-eye camera having an angle of view to enable imaging of the entire wafer W1 in the expanded state from the Z1 direction side.

### Nitrogen Supplier

As shown in FIGS. 40 and 41, the nitrogen supplier 4217 flows nitrogen into a space within the expansion maintaining member 4210 immediately before ultraviolet irradiation from the ultraviolet irradiator 212 such that oxygen is not supplied to a portion of the sheet member W2 on which the adhesive strength is to be reduced during ultraviolet irradiation from the ultraviolet irradiator 212.

The nitrogen supplier 4217 includes a first mounting member 4217a, a second mounting member 4217b, a third mounting member 4217c, and a nitrogen supply hose 4217d.

The first mounting member 4217a is attached to the edge of the through-hole 1210b on the Z1 direction-side surface of the lid 4210b of the expansion maintaining member 4210. The first mounting member 4217a has an X shape as viewed from the Z1 direction side. The imager 4215 is attached to a central portion of the Z2 direction-side surface of the first mounting member 4217a by a plurality of (four) screws 4217e.

The second mounting member 4217b is attached to the Z1 direction-side surface of the first mounting member 4217a. The second mounting member 4217b has an annular shape as viewed from the Z1 direction side. The second mounting member 4217b is a spacer that forms a space between the first mounting member 4217a and the third mounting member 4217c to allow nitrogen supplied through the nitrogen supply hose 4217d to flow thereinto.

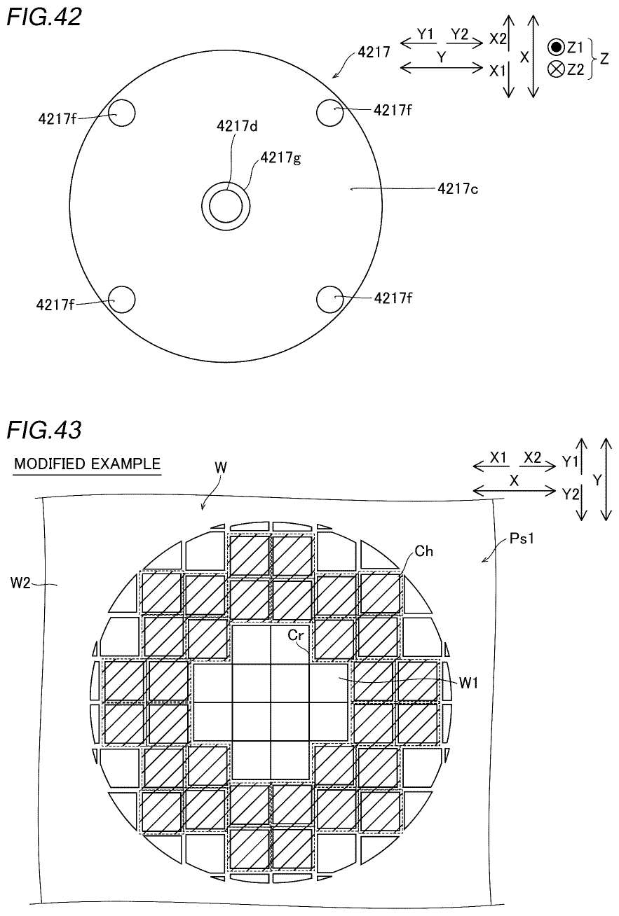

As shown in FIGS. 40 and 42, the third mounting member 4217c is attached to the Z1 direction-side surface of the second mounting member 4217b. The second mounting member 4217b has a circular shape as viewed from the Z1 direction side. The third mounting member 4217c is a cover that covers the through-hole 1210b from the Z1 direction side.

The first mounting member 4217a, the second mounting member 4217b, and the third mounting member 4217c are all attached to the edge of the through-hole 1210b of the lid 210b on the Z1 direction side by a plurality of (four) screws 4217f.

The nitrogen supply hose 4217d supplies nitrogen to the space within the expansion maintaining member 4210 through a space between the first mounting member 4217a and the third mounting member 4217c. The nitrogen supply hose 4217d is attached to a central portion of the third mounting member 4217c in the horizontal direction through a hose joint 4217g. The nitrogen supply hose 4217d is connected to a nitrogen supply source (not shown).

Thus, oxygen in the expansion maintaining member 4210 is expelled through the air release hole 4211a by nitrogen such that oxygen is not supplied to the portion of the sheet member W2 on which the adhesive strength is to be reduced during ultraviolet irradiation, and thus the adhesive strength of the sheet member W2 can be reduced by ultraviolet irradiation from the ultraviolet irradiator 212. The remaining configurations of the third embodiment are similar to those of the first embodiment, and thus description thereof is omitted.

### Advantageous Effects of Third Embodiment

According to the third embodiment, the following advantageous effects are achieved.

According to the third embodiment, similarly to the first embodiment, the expanding device 402 includes the imager 4215 to image the expanded state of the wafer W1 by the expanding ring 281 at a plurality of timings from the expansion start time St to the expansion end time Ed of the sheet member W2. Accordingly, it is possible to prevent the possibility that the wafer W1 will not be divided into the plurality of semiconductor chips Ch. The remaining advantageous effects of the third embodiment are similar to those of the first embodiment, and thus description thereof is omitted.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

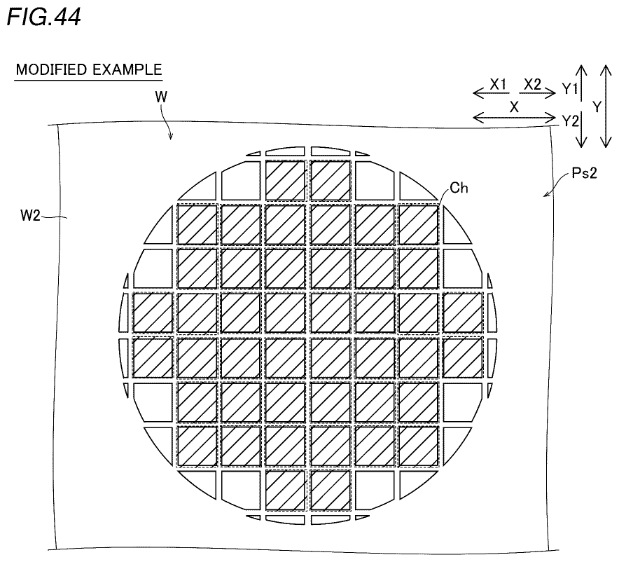

For example, while the example in which the imager 215 (4215) images the state of the sheet member W2 expanded by the expanding ring 281 (3281) has been shown in each of the aforementioned first to third embodiments, the present disclosure is not restricted to this. In the present disclosure, as in a modified example shown in FIGS. 43 and 44, the imager 215 (4215) may capture a captured image Ps1 and a captured image Ps2 before and after the wafer W1 is pressed by the squeegee unit 213 (3213). The captured image Ps1 is an image captured by the imager 215 (4215) before the wafer W1 is pressed, and the captured image Ps2 is an image captured by the imager 215 (4215) after the wafer W1 is pressed. That is, the expanding device 2 (302, 402) includes the squeegee unit 213 (3213) at a position in the downward direction with respect to the imager 215 (4215) to locally press the wafer W1 from below after the sheet member W2 is expanded by the expanding ring 281 (3281). The imager 215 (4215) captures images before and after the squeegee unit 213 (3213) locally presses the wafer W1 after the sheet member W2 is expanded by the expanding ring 281 (3281). Accordingly, the number of semiconductor chips Ch separated by the pressing of the squeegee unit 213 (3213) can be acquired from the captured image Ps1 captured by the imager 215 (4215) before the squeegee unit 213 (3213) locally presses the wafer W1 and the captured image Ps2 captured by the imager 215 (4215) after the squeegee unit 213 (3213) locally presses the wafer W1.

While the example in which the imager 215 (4215) captures a moving image including a plurality of captured images has been shown in each of the aforementioned first to third embodiments, the present disclosure is not restricted to this. In the present disclosure, the imager may perform high-speed imaging in which a plurality of captured images are captured. In other words, the imager images the expanded state of the wafer by the expanding ring using high-speed imaging in which a plurality of images are captured at a plurality of consecutive timings with shorter time intervals than those in normal moving image capturing from the start of expansion of the sheet member to the end of expansion of the sheet member. Accordingly, the imager performs high-speed imaging such that the detailed expanded state of the wafer from the start of expansion of the sheet material to the end of expansion of the sheet member can be acquired, and thus the timing at which the plurality of semiconductor chips have been separated can be acquired more precisely.

While the example in which the imager 215 (4215) captures a moving image including a plurality of captured images captured at a plurality of consecutive timings has been shown in each of the aforementioned first to third embodiments, the present disclosure is not restricted to this. In the present disclosure, the imager may intermittently capture a plurality of images as still images.

While the example in which the imager 215 (4215) is attached to the expansion maintaining member 210 (4210) has been shown in each of the aforementioned first to third embodiments, the present disclosure is not restricted to this. In the present disclosure, the imager may be attached to the upper base of the expanding device.

While the example in which the imager 215 is attached to the lid 210b of the expansion maintaining member 210 (4210) has been shown in each of the aforementioned first to third embodiments, the present disclosure is not restricted to this. In the present disclosure, the imager may be attached to the pressing ring.

While the example in which the imager 215 is attached to the central portion of the lid 210b of the expansion maintaining member 210 (4210) has been shown in each of the aforementioned first to third embodiments, the present disclosure is not restricted to this. In the present disclosure, the imager may be attached to a portion other than the central portion of the lid.

While the example in which the expansion maintaining member 210 (4210) includes the lid 210b has been shown in each of the aforementioned first to third embodiments, the present disclosure is not restricted to this. In the present disclosure, the expansion maintaining member may not include the lid.

While the example in which the notifier 216 includes a display to notify the user of the abnormality in the expanded state of the wafer W1 by displaying the abnormality on the screen has been shown in each of the aforementioned first to third embodiments, the present disclosure is not restricted to this. In the present disclosure, instead of the notifier notifying the user of the abnormality in the expanded state of the wafer, the abnormality in the expanded state of the wafer may be recorded in a storage.

While the example in which the expansion control calculator 109 (3110) determines that the semiconductor chips Ch separated from the wafer W1 have been detected when the outer shape of the semiconductor chip Ch in a plan view matches the shape of the semiconductor chip Ch separated from the wafer W1 in the plurality of images captured by the imager 215 has been shown in each of the aforementioned first to third embodiments, the present disclosure is not restricted to this. In the present disclosure, the expansion control calculator may acquire a distance between the detected adjacent semiconductor chips based on the horizontal position coordinates, inclinations, and dimensions of the semiconductor chips detected in the plurality of images captured by the imager, and determine whether or not the semiconductor chips separated from the wafer have been detected.

While the example in which the expanding device 2 (302, 402) includes the squeegee unit 213 (3213) has been shown in each of the aforementioned first to third embodiments, the present disclosure is not restricted to this. In the present disclosure, the expanding device may not include the squeegee unit.

While the control process of the expansion control calculator 109 (3110) is described, using the flowchart described in a manner driven by a flow in which processes are performed in order along a process flow for the convenience of illustration in each of the aforementioned first to third embodiments, the present disclosure is not restricted to this. In the present disclosure, the control process of the expansion control calculator may be performed in an event-driven manner in which processes are performed on an event basis. In this case, the control process may be performed in a complete event-driven manner or in a combination of an event-driven manner and a manner driven by a flow.

What is claimed is:

1. An expanding device comprising:
a clamp configured to hold a wafer ring structure including an elastic sheet member to which a wafer to be divided along a dividing line into a plurality of semiconductor chips has been attached;
an expanding ring configured to divide the wafer into the plurality of semiconductor chips spaced apart from each other by expanding the sheet member while the clamp unit holds the wafer ring structure; and
an imager configured to image an expanded state of the wafer by the expanding ring at a plurality of timings from a start of expansion of the sheet member to an end of expansion of the sheet member.

2. The expanding device according to claim 1, wherein
the imager is configured to capture a moving image including a plurality of captured images obtained by imaging the expanded state of the wafer by the expanding ring at a plurality of consecutive timings from the start of expansion of the sheet member to the end of expansion of the sheet member.

3. The expanding device according to claim 1, further comprising:
an expansion maintaining member configured to maintain an expanded state of the sheet member in a vicinity of the wafer; wherein
the imager is attached to the expansion maintaining member.

4. The expanding device according to claim 3, wherein the expansion maintaining member includes:
a cylindrical pressing ring surrounding the wafer; and
a lid configured to cover the pressing ring; and
the imager is attached to the lid of the expansion maintaining member.

5. The expanding device according to claim 4, wherein the imager is in a central portion of the lid in a radial direction of the pressing ring.

6. The expanding device according to claim 3, further comprising:
a member movement mechanism configured to move the expansion maintaining member in an upward-downward direction; wherein
the imager is configured to image the expanded state of the wafer by the expanding ring in a state in which the expansion maintaining member lowered by the member movement mechanism covers the wafer.

7. The expanding device according to claim 4, further comprising:
an ultraviolet irradiator at a position in a downward direction with respect to the imager to irradiate the sheet member in the expanded state with ultraviolet rays from below; wherein
the expansion maintaining member is configured to cover the wafer from above with the cylindrical pressing ring and the lid to prevent the ultraviolet rays radiated from the ultraviolet irradiator to the sheet member from leaking from the expansion maintaining member to an outside.

8. The expanding device according to claim 1, further comprising:
a notifier configured to notify a user of an abnormality in the expanded state of the wafer based on an imaging result of the expanded state of the wafer by the imager.

9. The expanding device according to claim 1, further comprising:
a clamp movement mechanism configured to move the clamp unit in an upward-downward direction; wherein
the expanding device is configured to expand the sheet member by moving down the clamp using the clamp movement mechanism while an upper end of the expanding ring is located at a predetermined height position in the upward-downward direction; and
the imager is configured to image the expanded state of the wafer by the expanding ring with the upper end located at the predetermined height position.

10. The expanding device according to claim 1, further comprising:
a squeegee at a position in a downward direction with respect to the imager and configured to locally press the wafer from below after the sheet member is expanded by the expanding ring; wherein
the imager is configured to capture images before and after the squeegee locally presses the wafer after the sheet member is expanded by the expanding ring.

11. A semiconductor chip manufacturing method comprising:
forming a modified layer in a wafer including a plurality of individual semiconductor chips by emitting a laser beam to the wafer from a laser irradiator configured to emit the laser beam; and
imaging, by an imager, an expanded state of the wafer by an expanding ring at a plurality of timings from a start of expansion of an elastic sheet member to which the wafer has been attached to an end of expansion of the sheet member while the expanding ring divides the wafer into the plurality of individual semiconductor chips by expanding the sheet member in a state in which a clamp configured to hold a wafer ring structure including the sheet member holds the wafer ring structure.

12. A semiconductor chip manufactured by an expanding device, the expanding device comprising:
a clamp configured to hold a wafer ring structure including an elastic sheet member to which a wafer to be divided along a dividing line into a plurality of semiconductor chips has been attached;
an expanding ring configured to divide the wafer into the plurality of semiconductor chips spaced apart from each other by expanding the sheet member while the clamp unit holds the wafer ring structure; and
an imager configured to image an expanded state of the wafer by the expanding ring at a plurality of timings from a start of expansion of the sheet member to an end of expansion of the sheet member.
